(19) United States
(12) Patent Application Publication
(10) Pub. No.: US 2026/0095148 A1
(43) Pub. Date: Apr. 2, 2026

(54) ACOUSTIC WAVE DEVICE AND ACOUSTIC WAVE FILTER DEVICE

(71) Applicant: Murata Manufacturing Co., Ltd., Nagaokakyo-shi (JP)

(72) Inventors: Yuta ISHII, Nagaokakyo-shi (JP); Katsuya DAIMON, Nagaokakyo-shi (JP); Akihiro IYAMA, Nagaokakyo-shi (JP)

(21) Appl. No.: 19/413,063

(22) Filed: Dec. 9, 2025

Related U.S. Application Data
(63) Continuation of application No. PCT/JP2024/021586, filed on Jun. 13, 2024.

(30) Foreign Application Priority Data
Jun. 13, 2023 (JP) 2023-097132

(51) Int. Cl. H03H 9/54; H03H 9/13

(52) U.S. Cl. CPC H03H 9/54; H03H 9/133

(57) ABSTRACT

An acoustic wave device includes a piezoelectric layer including first and second main surfaces facing in a first direction, an IDT electrode on at least one of the first or second main surface and including electrode fingers arranged in an arrangement direction, a support facing the second main surface and including an acoustic reflection portion, and a protective film on at least one of the first or second main surface. In a region that overlaps, in plan view in the first direction, a first of the electrode fingers outermost in the arrangement direction, the protective film includes a surface of a first step where a side surface of the protective film is exposed in a direction intersecting an extending direction of the first electrode finger. When d is a thickness of the piezoelectric layer and p is a center-to-center distance between adjacent electrode fingers, d/p is about 0.5 or less.

### CROSS REFERENCE TO RELATED APPLICATIONS

This application claims the benefit of priority to Japanese Patent Application No. 2023-097132 filed on Jun. 13, 2023 and is a Continuation Application of PCT Application No. PCT/JP2024/021586 filed on Jun. 13, 2024. The entire contents of each application are hereby incorporated herein by reference.

### BACKGROUND OF THE INVENTION

### 1. Field of the Invention

The present invention relates to acoustic wave devices and acoustic wave filter devices.

### 2. Description of the Related Art

Acoustic wave devices are described in Japanese Unexamined Patent Application Publication No. 2022-524136 and U.S. Pat. No. 11,349,450.

### SUMMARY OF THE INVENTION

There is the possibility of leakage of acoustic waves occurring in the arrangement direction of the electrode fingers in the acoustic wave devices described in Japanese Unexamined Patent Application Publication No. 2022-524136 and U.S. Pat. No. 11,349,450.

Example embodiments of the present invention provide acoustic wave devices and acoustic wave filter devices that reduce or prevent leakage of acoustic waves.

An acoustic wave device according to an example embodiment includes a piezoelectric layer including a first main surface and a second main surface facing the first main surface in a first direction, an IDT electrode provided on at least one of the first main surface or the second main surface of the piezoelectric layer and including a plurality of electrode fingers arranged in an arrangement direction, a support facing the second main surface of the piezoelectric layer and including an acoustic reflection portion on a side adjacent to the second main surface of the piezoelectric layer, and a protective film provided on at least one of the first main surface or the second main surface of the piezoelectric layer. In a region that overlaps, in plan view in the first direction, a first electrode finger, among the plurality of electrode fingers, that is located outermost in the arrangement direction, the protective film includes a surface of a first step where a side surface of the protective film is exposed in a direction intersecting a direction in which the first electrode finger extends. When d is a thickness of the piezoelectric layer and p is a center-to-center distance between adjacent electrode fingers, d/p is about 0.5 or less.

An acoustic wave filter device according to an example embodiment includes at least one resonator including the acoustic wave device described above.

Acoustic wave devices and acoustic wave filter devices according to example embodiments of the present invention reduce or prevent leakage of acoustic waves.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view illustrating an acoustic wave device of a First Example Embodiment of the present invention.

FIG. 2 is a sectional view taken along line II-II′ in FIG. 1.

FIG. 3 is a schematic sectional view for explaining bulk waves in a first-order thickness-shear mode propagating through a piezoelectric layer in the First Example Embodiment of the present invention.

FIG. 4 is a schematic sectional view for explaining the amplitude direction of bulk waves in a first-order thickness-shear mode propagating through the piezoelectric layer in the First Example Embodiment of the present invention.

FIG. 5 is a diagram illustrating an example of resonance characteristics of the acoustic wave device of the First Example Embodiment of the present invention.

FIG. 6 is an explanatory diagram illustrating the relationship between d/2p and the fractional bandwidth of a resonator in the acoustic wave device of the First Example Embodiment, where p is the center-to-center distance or the average center-to-center distance between adjacent electrodes and d is the average thickness of the piezoelectric layer.

FIG. 7 is a plan view illustrating an example in which a pair of electrodes is provided in the acoustic wave device of the First Example Embodiment of the present invention.

FIG. 8 is a reference diagram illustrating an example of resonance characteristics of the acoustic wave device of the First Example Embodiment of the present invention.

FIG. 9 is an explanatory diagram illustrating the relationship between the fractional bandwidth and the amount of phase rotation of impedance of a spurious signal, normalized by 180 degrees as the magnitude of the spurious signal, for the acoustic wave device of the First Example Embodiment when a large number of acoustic wave resonators are configured.

FIG. 10 is an explanatory diagram illustrating the relationship between d/2p, metallization ratio MR, and fractional bandwidth.

FIG. 11 is an explanatory diagram illustrating a map of the fractional bandwidth for the Euler angles (0°, θ, ψ) of LiNbO₃ when d/p is as close to 0 as possible.

FIG. 12 is an enlarged sectional view of region A illustrated in FIG. 2.

FIG. 13 is a graph illustrating an example of admittance characteristics of the acoustic wave device according to the First Example Embodiment of the present invention.

FIG. 14 is a sectional view of an acoustic wave device according to a First Modification of the First Example Embodiment of the present invention.

FIG. 15 is an explanatory diagram illustrating a vibration mode distribution of the acoustic wave device according to the First Modification of the First Example Embodiment of the present invention.

FIG. 16 is an explanatory diagram illustrating a vibration mode distribution of an acoustic wave device according to a comparative example.

FIG. 17 is a sectional view of an acoustic wave device according to a Second Example Embodiment of the present invention.

FIG. 18 is a graph illustrating an example of admittance characteristics of the acoustic wave device according to the Second Example Embodiment of the present invention.

FIG. 19 is a sectional view of an acoustic wave device according to a Third Example Embodiment of the present invention.

FIG. 20 is a sectional view of an acoustic wave device according to a Fourth Example Embodiment of the present invention.

FIG. 21 is a sectional view of an acoustic wave device according to a Fifth Example Embodiment of the present invention.

FIG. 22 is a sectional view of an acoustic wave device according to a Second Modification of the Fifth Example Embodiment of the present invention.

FIG. 23 is a sectional view of an acoustic wave device according to a Sixth Example Embodiment of the present invention.

FIG. 24 is a graph illustrating an example of admittance characteristics of the acoustic wave device according to the Sixth Example Embodiment of the present invention.

FIG. 25 is a plan view illustrating an acoustic wave device according to a Seventh Example Embodiment of the present invention.

FIG. 26 is a sectional view taken along line XXVI-XXVI′ in FIG. 25.

FIG. 27 is an enlarged sectional view of region A illustrated in FIG. 26.

FIG. 28 is a graph illustrating an example of admittance characteristics of the acoustic wave device according to the Seventh Example Embodiment of the present invention.

FIG. 29 is a sectional view of an acoustic wave device according to a Third Modification of the Seventh Example Embodiment of the present invention.

FIG. 30 is a graph illustrating an example of admittance characteristics of the acoustic wave device according to the Third Modification of the Seventh Example Embodiment of the present invention.

FIG. 31 is a sectional view of an acoustic wave device according to an Eighth Example Embodiment of the present invention.

FIG. 32 is a circuit diagram illustrating an acoustic wave filter device according to a Ninth Example Embodiment of the present invention.

FIG. 33 is a sectional view of an acoustic wave device according to a Tenth Example Embodiment of the present invention.

FIG. 34 is a graph illustrating an example of admittance characteristics of an acoustic wave device according to an Eleventh Example Embodiment of the present invention.

FIG. 35 is an explanatory diagram illustrating an example of impedance phase in a higher-order mode.

### DETAILED DESCRIPTION OF THE EXAMPLE EMBODIMENTS

Hereinafter, example embodiments of the present disclosure will be described in detail based on the drawings. However, the present disclosure is not limited to these example embodiments. Note that each example embodiment described in the present disclosure is an example, and description of matters common to the First Example embodiment will be omitted and only the differences will be described in the descriptions of modifications in which portions of the configurations illustrated in different example embodiments can be substituted or combined with each other and in the description of second and subsequent example embodiments. In particular, the same or similar effects resulting from the same or similar configurations are not repeatedly described in individual example embodiments.

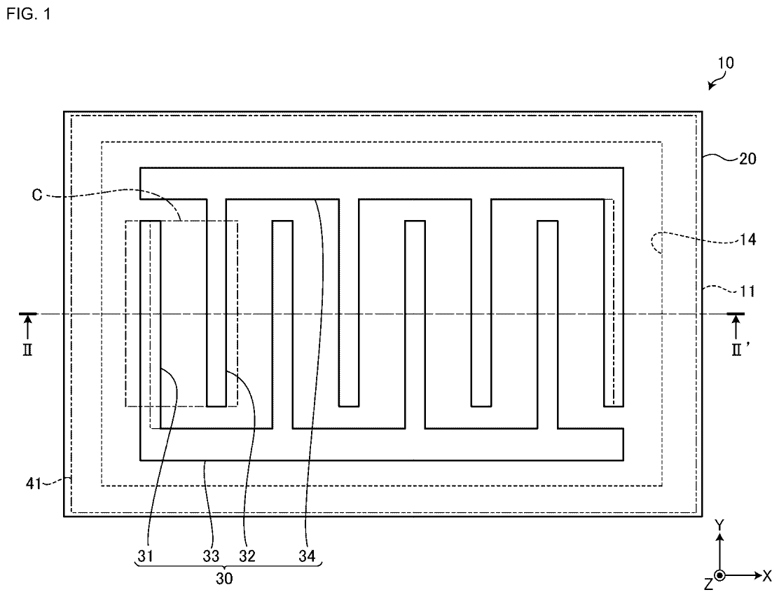

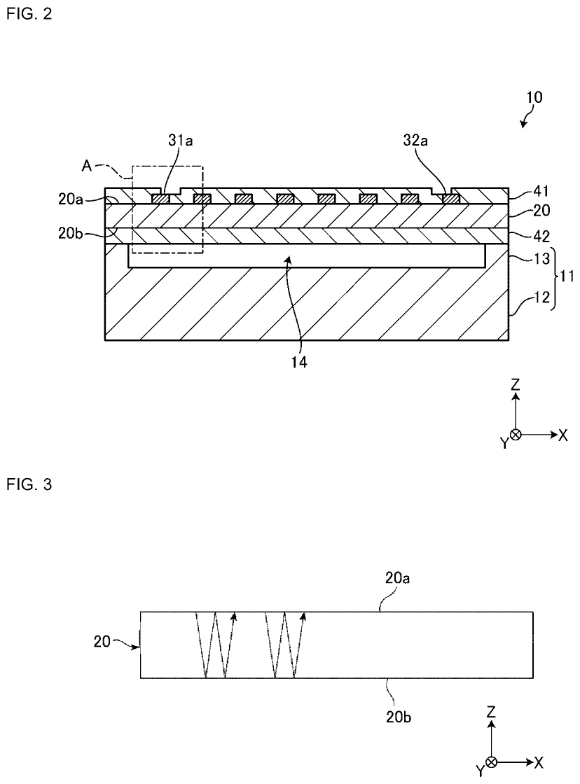

FIG. 1 is a plan view illustrating an acoustic wave device of a First Example Embodiment. FIG. 2 is a sectional view taken along line II-II′ in FIG. 1. Note that a first protective film 41 is indicated by a two-dot chain line in FIG. 1.

As illustrated in FIGS. 1 and 2, an acoustic wave device 10 according to the First Example Embodiment includes a piezoelectric layer 20, an IDT electrode 30, a support substrate 11, the first protective film 41, and a second protective film 42. As illustrated in FIG. 2, the acoustic wave device 10 includes the second protective film 42, the piezoelectric layer 20, the IDT electrode 30, and the first protective film 41 stacked in this order on the support substrate 11.

The piezoelectric layer 20 is shaped like a flat plate and includes a first main surface 20a and a second main surface 20b on the opposite side from the first main surface 20a. The piezoelectric layer 20 is formed of lithium niobate (LiNbO₃). Alternatively, the piezoelectric layer 20 may include lithium tantalate (LiTaO₃). In the First Example Embodiment, the cut angle of the LiNbO₃ or LiTaO₃ is Z-cut. The cut angle of the LiNbO₃ or LiTaO₃ may be rotated Y-cut or X-cut. Propagation directions along the Y direction and along directions within ±30° relative to the X direction are preferred. Preferably, the piezoelectric layer 20 includes lithium niobate (LiNbO₃) or lithium tantalate (LiTaO₃) and is 120°±10° rotated Y-cut or 90°±10° rotated Y-cut, for example. Here, 120°±10° includes a range of 120°−10° or more and 120°+10° or less, and 90°±10° includes a range of 90°−10° or more and 90°+10° or less, for example.

The thickness of the piezoelectric layer 20 is not particularly limited, but is preferably about 50 nm or more and about 1000 nm or less, for example, in order to effectively excite the first-order thickness-shear mode. The film thickness of the piezoelectric layer 20 according to the First Example Embodiment is, for example, about 180 nm.

The IDT (Interdigital Transducer) electrode 30 is provided on the first main surface 20a of the piezoelectric layer 20. As illustrated in FIG. 1, the IDT electrode 30 includes electrode fingers 31 and 32 and busbar electrodes 33 and 34. The plurality of electrode fingers 31 extend in the Y direction, and ends thereof on one side in the extension direction are connected to the busbar electrode 33. The plurality of electrode fingers 32 extend in the Y direction, and the ends thereof on the other side in the extension direction are connected to the busbar electrode 34. The plurality of electrode fingers 31 and the plurality of electrode fingers 32 are disposed in an alternating manner in the X direction with gaps therebetween. The busbar electrodes 33 and 34 each extend in the X direction, and are disposed spaced apart from each other in the Y direction. The plurality of electrode fingers 31 and 32 are disposed between the busbar electrode 33 and the busbar electrode 34.

In the following description, the thickness direction of the piezoelectric layer 20 may be referred to as the Z direction, the extension direction of the electrode fingers 31 and 32 may be referred to as the Y direction, and the arrangement direction of the electrode fingers 31 and 32 may be referred to as the X direction. In the following description, a plan view refers to the arrangement when viewed in a direction perpendicular to the first main surface 20a of the piezoelectric layer 20.

The center-to-center distance between the electrode fingers 31 and 32 (hereinafter referred to as inter-electrode pitch) is preferably in the range of about 1 μm or more and about 10 μm or less, for example. The inter-electrode pitch is the distance between the center of the width of any electrode finger 31 in a direction perpendicular to the extension direction of electrode finger 31 and the center of the width of the adjacent electrode finger 32 in a direction perpendicular to the extension direction of electrode finger 32. The width of electrode fingers 31 and 32 (hereinafter referred to as electrode width), i.e., the dimension in the direction perpendicular to the extension direction of the electrode fingers 31 and 32, is preferably in the range of about 150 nm or more and about 1000 nm or less, for example.

Furthermore, when there is a plurality of at least either of the electrode fingers 31 or the electrode fingers 32 (when there are 1.5 or more pairs of electrodes, where an electrode finger 31 and an electrode finger 32 are considered as a pair of electrodes), the inter-electrode pitch of the electrode fingers 31 and the electrode fingers 32 refers to the average value of the center-to-center distances of adjacent electrode fingers 31 and 32 among the 1.5 or more pairs of electrode fingers 31 and 32.

Furthermore, in the First Example Embodiment, since a Z-cut piezoelectric layer is used, a direction perpendicular to the extension direction of the electrode fingers 31 and 32 is perpendicular to the polarization direction of the piezoelectric layer 20. This does not apply if a piezoelectric material with a different cut angle is used as the piezoelectric layer 20. Here, the meaning of “perpendicular” is not limited to strictly perpendicular, and may also mean approximately perpendicular (for example, the angle between the direction perpendicular to the extension direction of the electrode fingers 31 and 32 and the polarization direction is about 90°±10°).

The IDT electrode 30 (electrode fingers 31 and 32 and busbar electrodes 33 and 34) includes an appropriate metal or alloy such as Al or an AlCu alloy. In the First Example Embodiment, the IDT electrode 30 has a structure in which an Al film is stacked on a titanium (Ti) film. Note that an adhesive layer other than a Ti film may also be used.

More specifically, the electrode configuration of the IDT electrode 30 is a multilayer film of Ti/AlCu/Ti/AlCu with respective film thicknesses of about 12 nm/70 nm/18 nm/12 nm from the piezoelectric layer 20 side, for example. The IDT electrode 30 has a total of 51 electrode fingers 31 and 32. The inter-electrode pitch between the electrode fingers 31 and 32 is about 2.38 μm, and the width of each electrode is about 0.6 μm, for example.

An intersecting region C (excitation region) illustrated in FIG. 1 is a region where the electrode fingers 31 and the electrode fingers 32 overlap when viewed in the X direction. The length of the intersecting region C is the dimension in the extension direction of the electrode fingers 31 and 32 in the intersecting region C. In this example embodiment, the length of the intersecting region C is, for example, about 40 μm.

During operation, an AC voltage is applied between the plurality of electrode fingers 31 and the plurality of electrode fingers 32. More specifically, an AC voltage is applied between the busbar electrode 33 and the busbar electrode 34. This allows resonance characteristics to be obtained using bulk waves in the first-order thickness-shear mode excited in the piezoelectric layer 20.

In addition, in acoustic wave device 10, d/p preferably is set to, for example, about 0.5 or less, where d is the thickness of piezoelectric layer 20 and p is the inter-electrode pitch of the multiple pairs of electrode fingers 31 and 32. Therefore, bulk waves in the first-order thickness-shear mode are effectively excited, resulting in good resonance characteristics. More preferably, d/p is set to about 0.24 or less, for example, and this results in even better resonance characteristics.

As a result of the acoustic wave device 10 of the First Example Embodiment having the above-described configuration, even if the number of pairs of electrode fingers 31 and 32 is reduced in an attempt to reduce the size of the device, the Q value is less likely to decrease. This is because the resonator does not require reflectors on either side, resulting in low propagation loss. Reflectors are not required because the device utilizes bulk waves in the first-order thickness-shear mode.

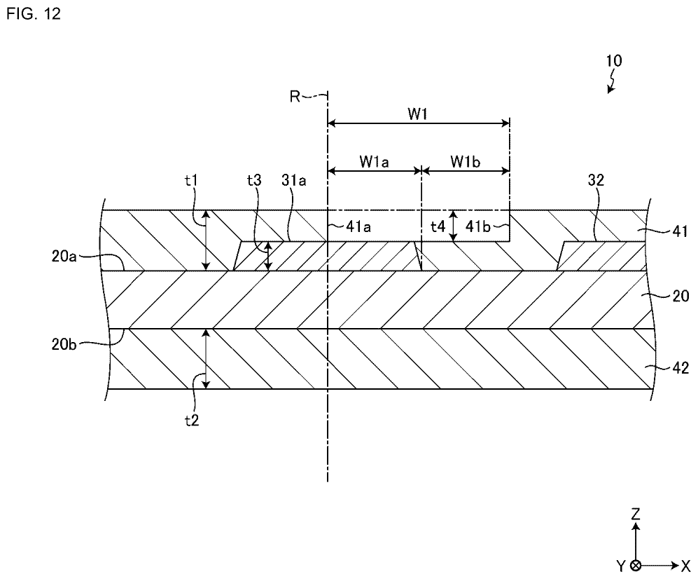

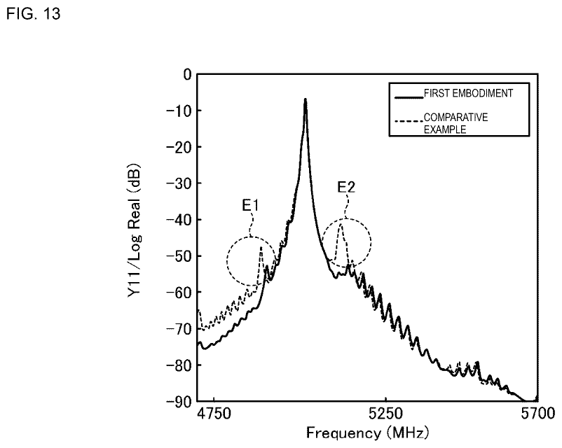

The first protective film 41 is provided on the first main surface 20a of the piezoelectric layer 20 so as to cover the IDT electrode 30. The second protective film 42 is provided on the second main surface 20b of the piezoelectric layer 20. The first protective film 41 and the second protective film 42 are composed of silicon oxide (SiO₂). The first protective film 41 and the second protective film 42 may include an appropriate insulating material other than silicon oxide such as silicon nitride or alumina. A film thickness t1 of the first protective film 41 and a film thickness t2 of the second protective film 42 are both 142 nm. The film thickness t1 of the first protective film 41 refers to the maximum total distance from the surface of the first protective film 41 on the first main surface 20a side to the surface of the first protective film 41 on the opposite side from the first main surface 20a in the intersecting region C. The film thickness t2 of the second protective film 42 refers to the maximum total distance from the surface of the second protective film 42 on the second main surface 20b side to the surface of the second protective film 42 on the opposite side from the second main surface 20b in the intersecting region C. It is sufficient that at least one of the first protective film 41 and the second protective film 42 be provided. For example, a configuration may be adopted in which the first protective film 41 is provided but the second protective film 42 is not provided. The detailed configurations of the first protective film 41 and the second protective film 42 will be described later with reference to FIGS. 12 and 13.

The support substrate 11 (support) is disposed opposite the second main surface 20b of the piezoelectric layer 20. The support substrate 11 has a cavity 14 (space) on the surface facing the second main surface 20b of the piezoelectric layer 20. More specifically, the support substrate 11 includes a bottom portion 12 and a wall portion 13 provided in a frame shape on the upper surface of the bottom portion 12. The cavity 14 is provided in the space surrounded by the bottom portion 12 and the wall portion 13. The piezoelectric layer 20 is stacked on the upper surface of the wall portion 13 of the support substrate 11 with the second protective film 42 interposed therebetween. Thus, the acoustic wave device 10 has a so-called membrane structure in which the cavity 14 (hollow portion) is provided on the second main surface 20b side of the piezoelectric layer 20. The support may include the support substrate 11 and an intermediate (insulating) layer. That is, the support substrate 11 may be indirectly stacked on the second main surface 20b of the piezoelectric layer 2. In this case, the support substrate 11 and the intermediate layer may have a frame shape to provide the cavity 14. Alternatively, a recess may be provided in the intermediate layer to provide the cavity 14.

The cavity 14 is provided so as not to interfere with vibration of the intersecting region C of the piezoelectric layer 20. The second protective film 42 is provided to cover the opening of the cavity 14. However, as described above, the second protective film 42 does not have to be provided. In this case, the support substrate 11 can be directly stacked on the second main surface 20b of the piezoelectric layer 20. Alternatively, the second protective film 42 may be provided in a region between the upper surface of the wall portion 13 and the second main surface 20b of the piezoelectric layer 20, but not in a region overlapping the cavity 14.

The support substrate 11 includes silicon (Si). The plane orientation of Si at the surface facing the piezoelectric layer 20 may be (100), (110), or (111). High-resistance Si with a resistivity of 4 kΩ or higher is preferable. However, the support substrate 11 may also be formed using an appropriate insulating material or semiconductor material. Examples of materials that can be used for the support substrate 11 include piezoelectric materials such as aluminum oxide, lithium tantalate, lithium niobate, and quartz, various ceramic materials such as alumina, magnesia, sapphire, silicon nitride, aluminum nitride, silicon carbide, zirconia, cordierite, mullite, steatite, and forsterite, dielectric materials such as diamond and glass, and semiconductors such as gallium nitride.

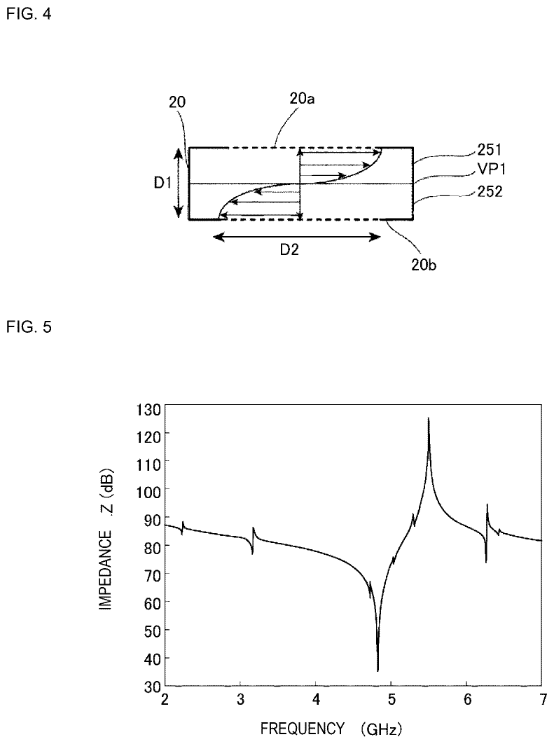

FIG. 3 is a schematic sectional view for explaining bulk waves in a first-order thickness-shear mode propagating through the piezoelectric layer in the First Example Embodiment. FIG. 4 is a schematic sectional view for explaining the amplitude direction of bulk waves in a first-order thickness-shear mode propagating through the piezoelectric layer of the First Example embodiment.

As illustrated in FIG. 3, in the acoustic wave device 10 of the First Example Embodiment, vibration displacement occurs in the thickness shear direction, and therefore, waves propagate and resonate almost entirely in a direction connecting the first main surface 20a and the second main surface 20b of the piezoelectric layer 20, i.e., the Z direction. That is, the X direction component of the waves is significantly smaller than the Z direction component. Furthermore, since resonance characteristics are achieved through the propagation of waves in the Z direction, reflectors are not required. Therefore, no propagation loss occurs during propagation to the reflectors. Therefore, even if the number of electrode pairs, each pair including an electrode finger 31 and an electrode finger 32, is reduced in an effort to achieve a reduction in the size, the Q value is less likely to decrease.

As illustrated in FIG. 4, the bulk waves in the first-order thickness-shear mode have opposite amplitude directions in a first region 251 included in the intersecting region C (see FIG. 1) of the piezoelectric layer 20 and a second region 252 included in the intersecting region C. FIG. 4 schematically illustrates a bulk wave when a voltage is applied between the electrode fingers 31 and 32 such that the electrode finger 32 has a higher potential than the electrode finger 31. Here, a virtual plane VP1 is a plane that is perpendicular to the thickness direction of the piezoelectric layer 20 and divides the piezoelectric layer 20 into two halves. The first region 251 is a region of the intersecting region C between the virtual plane VP1 and the first main surface 20a. The second region 252 is a region of the intersecting region C between the virtual plane VP1 and the second main surface 20b.

In the acoustic wave device 10, at least one pair of electrodes including an electrode finger 31 and an electrode finger 32 is disposed, but because the waves are not made to propagate in the X direction, there does not necessarily need to be a plurality of electrode pairs including an electrode finger 31 and an electrode finger 32. In other words, it is sufficient that at least one pair of electrodes be provided.

For example, the electrode finger 31 is an electrode connected to a hot potential, and the electrode finger 32 is an electrode connected to a ground potential. However, the electrode finger 31 may be connected to the ground potential, and the electrode finger 32 may be connected to the hot potential. In the First Example Embodiment, at least one pair of electrodes is an electrode connected to a hot potential or an electrode connected to a ground potential, as described above, and no floating electrode is provided.

FIG. 5 is a diagram illustrating an example of resonance characteristics of the acoustic wave device of the First Example Embodiment. The design parameters of acoustic wave device 10 with which the resonance characteristics illustrated in FIG. 5 are obtained are as follows.
Piezoelectric layer 20: LiNbO₃ with Euler angles (0°, 0°, 90°)
Thickness of piezoelectric layer 20: 400 nm
Length of intersecting region C: 40 μm
Number of pairs of electrodes including electrode finger 31 and electrode finger 32: 21 pairs
Inter-electrode pitch between electrode finger 31 and electrode finger 32: 3 μm
Width of electrode fingers 31 and 32: 500 nm
d/p: 0.133
First protective film 41, second protective film 42: silicon oxide film with a thickness of 1 μm
Support substrate 11: Si

In the First Example Embodiment, the inter-electrode pitch of the electrode pairs, each including the electrode finger 31 and the electrode finger 32, is set to be identical in all pairs. That is, the electrode fingers 31 and the electrode fingers 32 are disposed at identical pitches.

As is clear from FIG. 5, good resonance characteristics with a fractional bandwidth of about 12.5%, for example, are obtained despite the absence of reflectors.

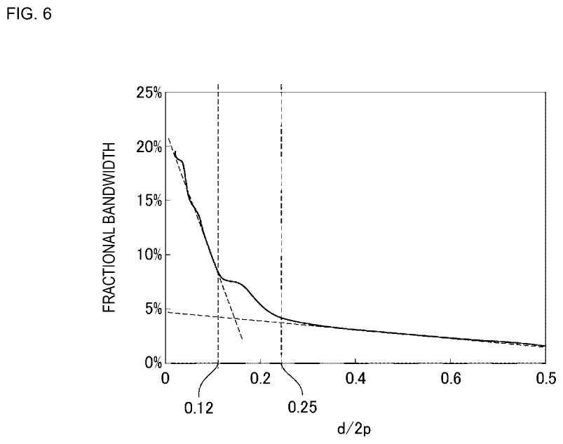

Incidentally, when d is the thickness of the piezoelectric layer 20 and p is the inter-electrode pitch between the electrode fingers 31 and 32, d/p is about 0.5 or less, and more preferably about 0.24 or less, for example, in the First Example Embodiment. This will be explained with reference to FIG. 6.

FIG. 6 is an explanatory diagram illustrating the relationship between d/2p and the fractional bandwidth as a resonator for the acoustic wave device of the First Example Embodiment, where p is the center-to-center distance or the average center-to-center distance between adjacent electrodes and d is the average thickness of the piezoelectric layer. In FIG. 6, multiple acoustic wave devices, substantially the same as the acoustic wave device having the resonance characteristics illustrated in FIG. 5, were obtained by varying d/2p.

As illustrated in FIG. 6, when d/2p exceeds about 0.25, i.e., when d/p>about 0.5, the fractional bandwidth is less than about 5% even when d/p is adjusted, for example. In contrast, when d/2p≤about 0.25, i.e., when d/p≤about 0.5, varying d/p within this range can increase the fractional bandwidth to about 5% or more, for example, to enable the construction of a resonator with a high coupling coefficient. Furthermore, when d/2p is about 0.12 or less, i.e., when d/p is about 0.24 or less, the fractional bandwidth can be increased to about 7% or more, for example. Furthermore, adjusting d/p within this range enables a resonator with a wider fractional bandwidth to be obtained and a resonator with an even higher coupling coefficient to be realized. Therefore, by setting d/p to about 0.5 or less, for example, a resonator with a high coupling coefficient that uses bulk waves in the first-order thickness-shear mode can be constructed.

When there are variations in a thickness d of the piezoelectric layer 20, the thickness d of the piezoelectric layer 20 may be an average value of the thicknesses.

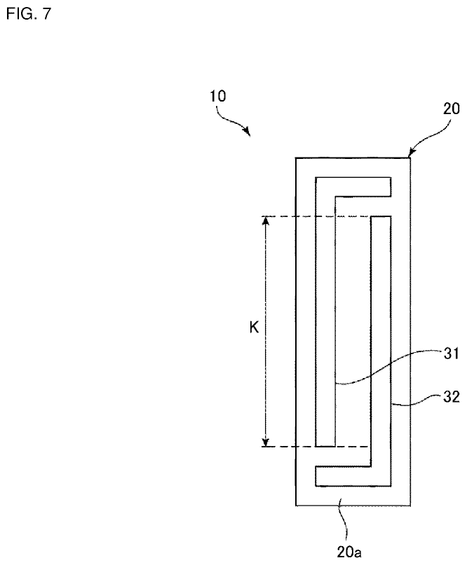

FIG. 7 is a plan view illustrating an example in which a pair of electrodes is provided in the acoustic wave device of the First Example Embodiment. In acoustic wave device 10, a pair of electrodes including the electrode finger 31 and the electrode finger 32 is provided on the first main surface 20a of piezoelectric layer 20. Note that K represents the intersecting width in FIG. 7. As described above, in the acoustic wave device 10 of the present disclosure, the number of pairs of electrodes may be one. Even in this case, provided that the above d/p is about 0.5 or less, for example, bulk waves in the first-order thickness-shear mode can be effectively excited.

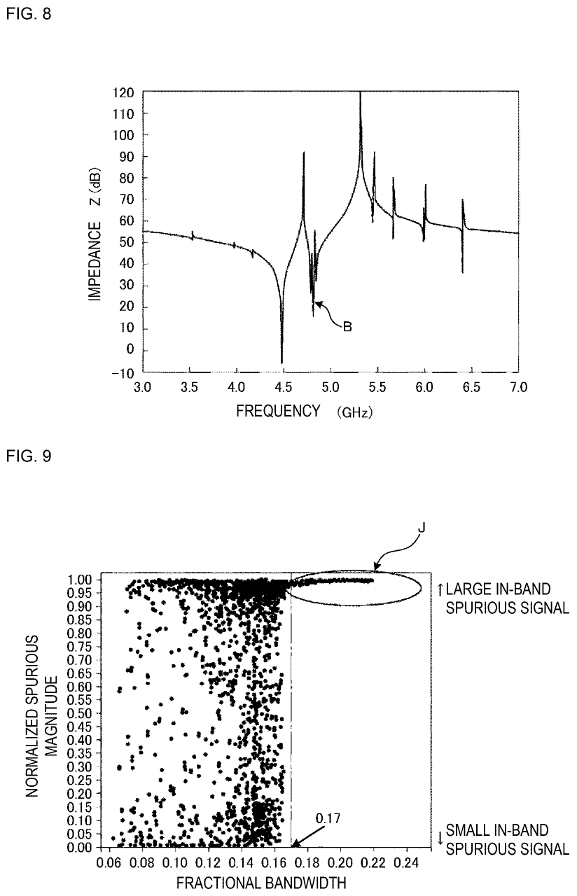

In the acoustic wave device 10, it is preferable that the metallization ratio MR of the adjacent electrode fingers 31 and 32 with respect to the intersecting region C satisfies MR≤about 1.75(d/p)+0.075, for example. In this case, a spurious signal can be effectively reduced. This will be explained with reference to FIGS. 8 and 9.

FIG. 8 is a reference diagram illustrating an example of the resonance characteristics of the acoustic wave device of the First Example Embodiment. As illustrated in FIG. 8, a spurious signal indicated by arrow B appears between the resonant frequency and the anti-resonant frequency. Note that d/p=about 0.08 and the Euler angles of LiNbO₃ were (0°, 0°, 90°), for example. The metallization ratio MR was about 0.35, for example.

The metallization ratio MR will be explained with reference to FIG. 1. Focusing on a pair of electrode fingers 31 and 32 in the electrode structure of FIG. 1, let us assume that only this pair of electrode fingers 31 and 32 is provided. In this case, the area surrounded by a dashed dotted line is the intersecting region C. When the electrode fingers 31 and 32 are viewed in a direction perpendicular to the extension direction of the electrode fingers 31 and 32, i.e., the opposing direction, the intersecting region C refers to the region of the electrode finger 31 that overlaps the electrode finger 32, the region of the electrode finger 32 that overlaps the electrode finger 31, and the region between the electrode fingers 31 and 32 where the electrode fingers 31 and 32 overlap. The metallization ratio MR is the ratio of the area of the electrode fingers 31 and 32 within the intersecting region C to the area of the intersecting region C. In other words, the metallization ratio MR is the ratio of the area of the metallization portion to the area of the intersecting region C.

When multiple pairs of electrode fingers 31 and electrode fingers 32 are provided, the ratio of the metallization portions included in the entire intersecting region C to the total area of the intersecting region C may be defined as MR.

FIG. 9 is an explanatory diagram illustrating the relationship between the fractional bandwidth and the amount of phase rotation of the impedance of a spurious signal, normalized by 180 degrees as the magnitude of the spurious signal, for the acoustic wave device of the First Example Embodiment when a large number of acoustic wave resonators are configured. The fractional bandwidth was adjusted by changing the film thickness of piezoelectric layer 20 and the dimensions of electrode fingers 31 and 32 to various values. Although FIG. 9 illustrates the results obtained when the piezoelectric layer 20 including Z-cut LiNbO₃ is used, similar trends are observed when piezoelectric layers 20 with other cut angles are used.

In the region surrounded by an ellipse J in FIG. 9, the spurious signal is as large as about 1.0, for example. As is clear from FIG. 9, when the fractional bandwidth exceeds about 0.17, i.e., exceeds about 17%, for example, a large spurious signal with a spurious level of 1 or higher appears within the passband, even if the parameters configuring the fractional bandwidth are changed. That is, as in the resonance characteristics illustrated in FIG. 8, a large spurious signal indicated by arrow B appears within the passband. Therefore, it is preferable that the fractional bandwidth be about 17% or less, for example. In this case, spurious signals can be reduced by adjusting the film thickness of the piezoelectric layer 20 and the dimensions of the electrode fingers 31 and 32, etc.

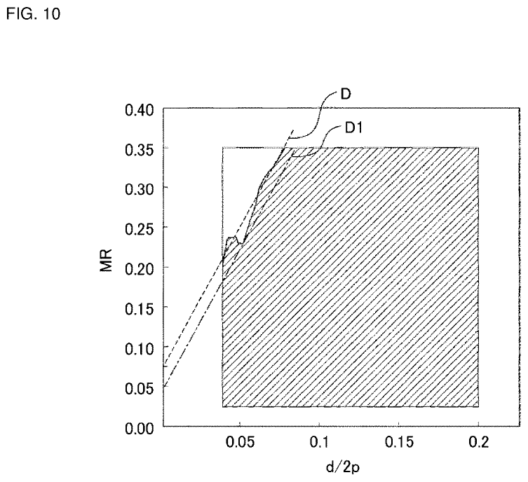

FIG. 10 is an explanatory diagram illustrating the relationship between d/2p, the metallization ratio MR, and the fractional bandwidth. Various acoustic wave devices 10 with different d/2p and MR were fabricated for the acoustic wave device 10 of the First Example Embodiment, and the fractional bandwidth was measured. The hatched area to the right of a dashed line D in FIG. 10 represents the region where the fractional bandwidth is 17% or less. The boundary between this hatched area and the unhatched area is represented by MR=about 3.5(d/2p)+0.075, for example. That is, MR=about 1.75(d/p)+0.075, for example. Therefore, preferably, MR≤about 1.75(d/p)+0.075, for example. In this case, the fractional bandwidth is easily maintained at 17% or less. The region to the right of MR=about 3.5(d/2p)+0.05, for example, as indicated by dashed dotted line D1 in FIG. 10, is more preferable. That is, if MR≤about 1.75(d/p)+0.05, the fractional bandwidth can be reliably maintained at about 17% or less, for example.

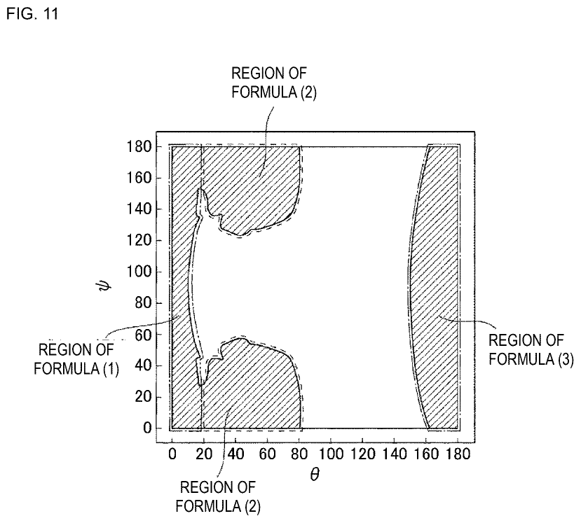

FIG. 11 is an explanatory diagram illustrating a map of the fractional bandwidth for the Euler angles (0°, θ, ψ) of LiNbO₃ when d/p is as close to 0 as possible. The hatched areas in FIG. 11 are the regions where a fractional bandwidth of at least 5% or more can be obtained. The ranges of these regions can be approximated as the ranges expressed by the following Formulas (1), (2), and (3).

(0°±10°, 0° to 20°, any ψ) Formula (1)

(0°±10°, 20° to 80°, 0° to 60°(1−(θ-50)²/900)^{1/2}) or (0°±10°, 20° to 80°, {180°−60°(1−(θ−50)²/900)^{1/2}} to 180°) Formula (2)

(0°±10°, {180°−30°(1−(ψ−90)²/8100)^{1/2}} to 180°, any ψ) Formula (3)

Therefore, in the case of the Euler angle range of the above Formula (1), Formula (2) or Formula (3), the fractional bandwidth can be made sufficiently wide, which is preferable.

Next, the detailed configuration of the first protective film 41 will be described. FIG. 12 is an enlarged sectional view of region A illustrated in FIG. 2. Note that although the portion of the first protective film 41 overlapping a first electrode finger 31a located outermost in the arrangement direction of the multiple electrode fingers 31 and 32 in FIG. 12 is described, the portion of the first protective film 41 overlapping a second electrode finger 32a located outermost on the opposite side from the first electrode finger 31a (see FIGS. 1 and 2) has a shape having linear symmetry with the portion of the first protective film 41 overlapping the first electrode finger 31a. The description of the first electrode finger 31a can also be applied to the second electrode finger 32a.

As illustrated in FIG. 12, in the region overlapping the first electrode finger 31a, the first protective film 41 includes the surface of a first step 41a where the side surface of the first protective film 41 is exposed along the Y direction. The side surface of the protective film refers to a surface that extends in a direction intersecting the surface of the protective film on the piezoelectric layer 20 side. In other words, the normal to the side surface of the protective film intersects the thickness direction of the protective film. In this example embodiment, the first step 41a is lower on the inner side in the arrangement direction of the multiple electrode fingers 31 and 32. Specifically, in the region overlapping the first electrode finger 31a, the first step 41a is defined by a portion where the first protective film 41 is not provided and a portion where the first protective film 41 is provided, from the inner side in the arrangement direction of the electrode fingers 31 and 32.

As illustrated in FIG. 12, in a region between the first electrode finger 31a and the electrode finger 32 adjacent to the first electrode finger 31a, the first protective film 41 includes a surface of a second step 41b where the side surface of the first protective film 41 is exposed along the Y direction. In this example embodiment, the second step 41b is lower on the outer side in the arrangement direction of the multiple electrode fingers 31 and 32. In this example embodiment, in the region between the first electrode finger 31a and the adjacent electrode finger 32, the second step 41b is defined by a portion where the first protective film 41 is thick and a portion where the first protective film 41 is thin, from the inner side in the arrangement direction of the multiple electrode fingers 31 and 32.

In the following description, the region between the first step 41a and the second step 41b will be referred to as an inter-step region. The height of a step refers to the difference in height from the main surface (first main surface 20a or second main surface 20b) of the piezoelectric layer 20 between the surface on the inner side and the surface on the outer side of the step in the arrangement direction, and corresponds to the length of the step surface in the Z direction.

The inter-step region is located at a position shifted inward relative to the first electrode finger 31a in the arrangement direction of the multiple electrode fingers 31 and 32. The side surface of the first protective film 41 at the first step 41a is disposed so as to overlap the midpoint of the first electrode finger 31a in the width direction, and the side surface of the first protective film at the second step 41b is disposed farther inward than the first electrode finger 31a in the arrangement direction. That is, the inter-step region includes an overlapping region that overlaps the first electrode finger 31a and a non-overlapping region that does not overlap the first electrode finger 31a. A width W1 of the region between the first step 41a and the second step 41b is, for example, about 0.6 μm. A width W1a of the overlapping region in the inter-step region is, for example, about 0.3 μm. A width W1b of the non-overlapping region in the inter-step region is, for example, about 0.3 μm. In this example embodiment, the upper surfaces of first electrode finger 31a and first protective film 41 in the inter-step region are flat. Specifically, the upper surfaces of the first electrode finger 31a and the first protective film 41 in the inter-step region are substantially flat across the region where the first electrode finger 31a is provided and the region where the first electrode finger 31a is not provided.

In this example embodiment, a height t4 of the first step 41a and the second step 41b is about 30 nm, for example. As described above, the film thickness t1 of the first protective film 41 and the film thickness t2 of the second protective film 42 are about 142 nm, and a film thickness t3 of the IDT electrode 30 is about 112 nm, for example. The film thickness t1 of the first protective film 41 is greater than the height t4 of the first step 41a and the second step 41b, and is also greater than the film thickness t3 of the IDT electrode 30. In this example embodiment, the inter-step region includes a region where the first protective film 41 is not provided. That is, the inter-step region includes a region where the first electrode finger 31a is exposed.

Thus, the first step 41a is provided to overlap the first electrode finger 31a, and therefore, in the region overlapping the first electrode finger 31a positioned outermost in the arrangement direction of the plurality of electrode fingers 31 and 32, the first protective film 41 is not provided in the region inward from the first step 41a in the arrangement direction and this region has a different acoustic impedance from the region where the first protective film 41 is stacked. As a result, an acoustic reflection surface R is provided at the first step (the portion overlapping the side surface of the first protective film 41).

As a result, the acoustic waves excited in the piezoelectric layer 20 are reflected by the acoustic reflection surface R, and therefore the acoustic wave device 10 can reduce or prevent leakage of acoustic waves in the arrangement direction of the multiple electrode fingers 31 and 32.

FIG. 13 is an explanatory diagram illustrating an example of the admittance characteristics of the acoustic wave device according to the First Example Embodiment. More specifically, FIG. 13 is an explanatory diagram illustrating the real portion of the admittance, i.e., the conductance component, of the acoustic wave device according to the First Example Embodiment. The admittance characteristics illustrated in FIG. 13 represent simulation results of the admittance characteristics of the acoustic wave device 10 according to the First Example Embodiment. FIG. 13 also illustrates simulation results of the admittance characteristics of an acoustic wave device according to a comparative example. The comparative example is an acoustic wave device that does not include the first step 41a and the second step 41b in contrast to the First Example Embodiment.

As illustrated in FIG. 13, in the acoustic wave device according to the comparative example, ripples occur in a frequency range different from the resonant frequency. In the comparative example, particularly large ripples are generated, as indicated by the dotted lines E1 and E2. In contrast, in acoustic wave device 10 according to the First Example Embodiment, as a result of providing the first step 41a and second step 41b, the ripples indicated by dotted lines E1 and E2 are reduced or prevented compared to the comparative example. It can be seen that, because the peak width associated with the resonant frequency is narrower in acoustic wave device 10 according to the First Example Embodiment than in the acoustic wave device according to the comparative example, propagation loss is reduced or prevented, and leakage of acoustic waves is reduced or prevented.

The above-described shapes, widths, film thicknesses, etc. of the first protective film 41 and the IDT electrode 30 are merely examples and can be changed as appropriate. For example, the first step 41a and the second step 41b may be formed with a tapered shape.

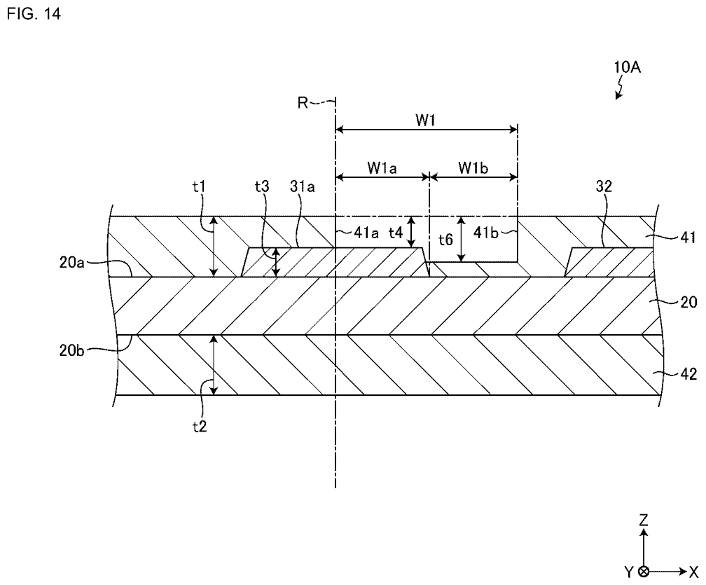

FIG. 14 is a sectional view of an acoustic wave device according to a First Modification of the First Example Embodiment. As illustrated in FIG. 14, in the First Modification of the First Example Embodiment, the height of the first step 41a is different from the height of the second step 41b, and the thickness of the first protective film 41 in the inter-step region is smaller than the thickness of the first electrode finger 31a. In the First Modification, in the region overlapping the first electrode finger 31a, the first protective film 41 includes a surface of the first step 41a where the side surface of the first protective film 41 is exposed along the Y direction. The first step 41a is lower on the inner side in the arrangement direction of the electrode fingers 31 and 32. Specifically, in the region overlapping the first electrode finger 31a, the first step 41a is defined by a portion where the first protective film 41 is not provided and a portion where the first protective film 41 is provided, from the inner side in the arrangement direction of the electrode fingers 31 and 32.

As illustrated in FIG. 14, in a region between the first electrode finger 31a and the electrode finger 32 adjacent to the first electrode finger 31a, the first protective film 41 includes a surface of the second step 41b where the side surface of the first protective film 41 is exposed along the Y direction. In the First Modification, the second step 41b is lower on the outer side in the arrangement direction of the multiple electrode fingers 31 and 32. In the First Modification, in the region between the first electrode finger 31a and the adjacent electrode finger 32, the second step 41b is defined by a portion where the first protective film 41 is thick and a portion where the first protective film 41 is thin, from the inner side in the arrangement direction of the multiple electrode fingers 31 and 32.

The inter-step region is located at a position shifted inward relative to the first electrode finger 31a in the arrangement direction of the multiple electrode fingers 31 and 32. The side surface of the first protective film 41 at the first step 41a is disposed so as to overlap the midpoint of the first electrode finger 31a in the width direction, and the side surface of the first protective film at the second step 41b is disposed farther inward than the first electrode finger 31a in the arrangement direction. That is, the inter-step region includes an overlapping region that overlaps the first electrode finger 31a and a non-overlapping region that does not overlap the first electrode finger 31a. A width W1 of the region between the first step 41a and the second step 41b is, for example, about 0.6 μm. A width W1a of the overlapping region in the inter-step region is, for example, about 0.3 μm. A width W1b of the non-overlapping region in the inter-step region is, for example, about 0.3 μm.

In the First Modification, a height t4 of the first step 41a is about 30 nm, and a height t6 of the second step 41b is about 40 nm, for example. As described above, the film thickness t1 of the first protective film 41 and the film thickness t2 of the second protective film 42 are about 142 nm, and the film thickness t3 of the IDT electrode 30 is about 112 nm, for example. The film thickness t1 of the first protective film 41 is greater than the height t4 of the first step 41a and the height t6 of the second step 41b, and is also greater than the film thickness t3 of the IDT electrode 30.

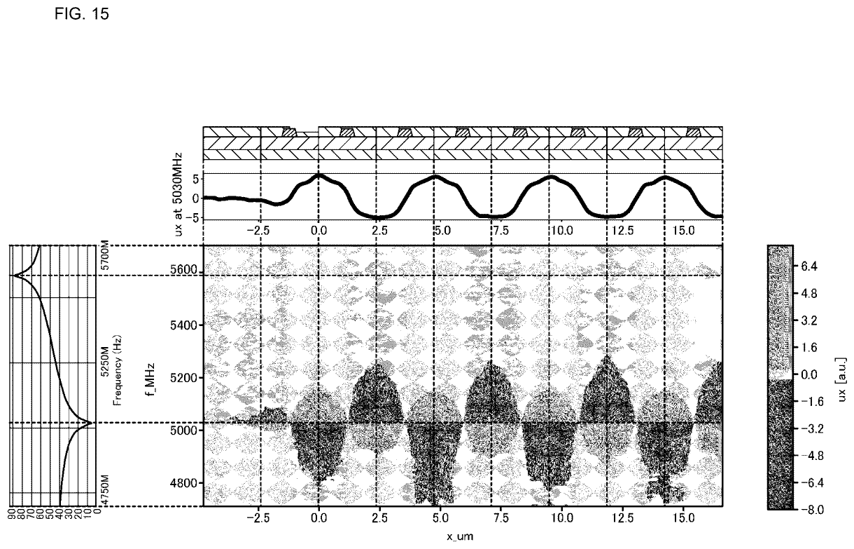

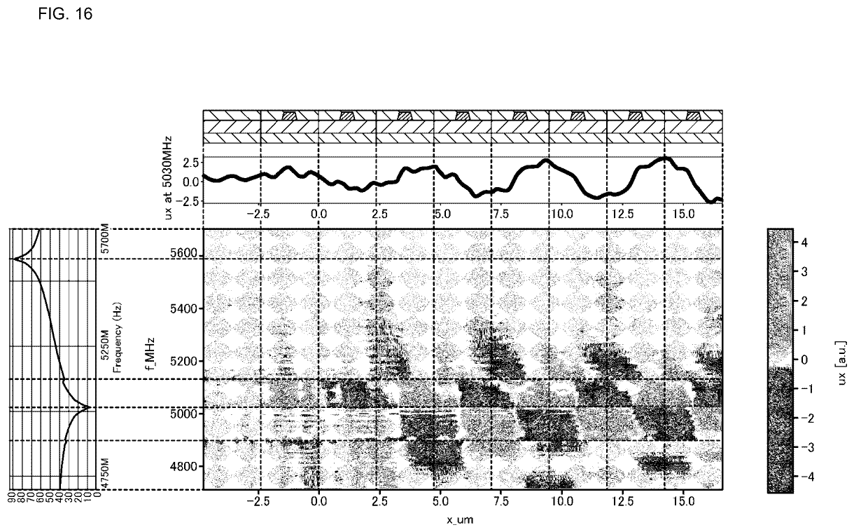

FIG. 15 is a diagram illustrating the vibration mode distribution of the acoustic wave device according to the First Modification. FIG. 16 is a diagram illustrating the vibration mode distribution of the acoustic wave device according to a comparative example. The comparative example illustrated in FIG. 16 is configured such that first step 41a and second step 41b are not provided in contrast to an acoustic wave device 10A according to the First Modification.

FIGS. 15 and 16 illustrate the distribution of the magnitude of displacement of the piezoelectric layer 20 for the First Modification and the comparative example, with the horizontal axis representing the X direction (the arrangement direction of the electrode fingers 31 and 32) and the vertical axis representing frequency. The upper portions of FIGS. 15 and 16 each schematically illustrate a sectional view of an acoustic wave device corresponding to the X direction, and the left portions of FIGS. 15 and 16 illustrate the impedance characteristics of the acoustic wave devices.

As illustrated in FIG. 16, in the acoustic wave device of the comparative example, the X-direction dependency of the displacement (the X-direction positions of the antinodes and nodes of the displacement) depends significantly on frequency. For example, the X-direction positions at which the peaks of the displacement are present are shifted depending on the frequency, and stable excitation between the electrodes is not achieved. Furthermore, focusing on a specific X-direction position (near X=5.0 μm), the phase is inverted at the resonant frequency of 5030 MHz and at frequencies of 4900 MHz and 5120 MHz where ripples occur. Thus, it might not be possible to realize an ideal excitation mode with the acoustic wave device of the comparative example.

In contrast, as illustrated in FIG. 15, in the acoustic wave device 10A according to the First Modification, the X-direction dependency of the displacement (the X-direction positions of the antinodes and nodes of the displacement) does not depend on the frequency. That is, the X-direction positions at which the displacement peaks are present are constant regardless of frequency, thus demonstrating stable excitation between the electrodes. Furthermore, the magnitude (amplitude) of the displacement is also constant for each inter-electrode region, and no phase inversion occurs at the frequency positions where the resonant frequency and ripples occur. Thus, it was demonstrated that a better excitation mode than in the comparative example can be obtained by simply providing the first step 41a at a position overlapping a portion of the first electrode finger 31a located outermost in the arrangement direction.

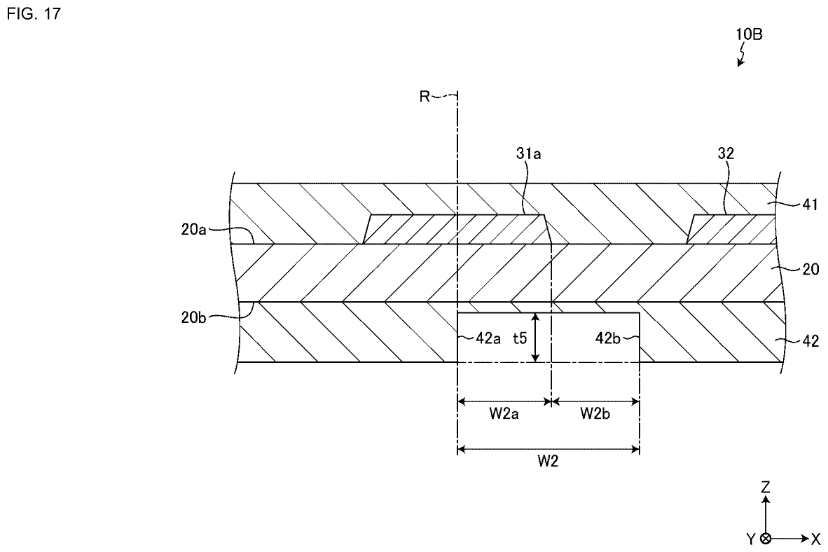

FIG. 17 is a sectional view of an acoustic wave device according to a Second Example Embodiment. In the First Example Embodiment and the First Modification, a configuration was described in which the first step 41a and the second step 41b are provided on the first protective film 41 on the first main surface 20a side of the piezoelectric layer 20. However, the configuration is not limited thereto. As illustrated in FIG. 17, in an acoustic wave device 10B according to the Second Example Embodiment, a first step 42a and a second step 42b are provided in the second protective film 42 on the second main surface 20b side of the piezoelectric layer 20. In other words, the step region is not on the first main surface 20a side of the piezoelectric layer 20, and the upper surface of the first protective film 41 is flat.

FIG. 17, in a region overlapping the first electrode finger 31a, the second protective film 42 includes a surface of the first step 42a where the side surface of the second protective film 42 is exposed along the Y direction. In this example embodiment, the first step 42a is lower on the inner side in the arrangement direction of the multiple electrode fingers 31 and 32. Specifically, in the region overlapping the first electrode finger 31a, the first step 42a is defined by a portion where the second protective film 42 is thin and a portion where the second protective film 42 is thick, from the inner side in the arrangement direction of the multiple electrode fingers 31 and 32.

As illustrated in FIG. 17, in the region between the first electrode finger 31a and the electrode finger 32 adjacent to the first electrode finger 31a, the second protective film 42 includes a surface of the second step 42b where the side surface of the second protective film 42 is exposed along the Y direction. In this example embodiment, the second step 42b is lower on the outer side in the arrangement direction of the multiple electrode fingers 31 and 32. The configuration of the IDT electrode 30, etc., is substantially the same as in the First Example Embodiment. In this example embodiment, in the region between the first electrode finger 31a and the adjacent electrode finger 32, the second step 42b is defined by a portion where the second protective film 42 is thick and a portion where the second protective film 42 is thin, from the inner side in the arrangement direction of the multiple electrode fingers 31 and 32.

In the following description, the region between the first step 42a and the second step 42b will be referred to as an inter-step region. The inter-step region is located inward from the first electrode finger 31a in the arrangement direction of the multiple electrode fingers 31 and 32. The side surface of the second protective film 42 at the first step 42a is disposed so as to overlap the midpoint of the first electrode finger 31a in the width direction, and the side surface of the second protective film 42 at the second step 42b is located farther inward than the first electrode finger 31a in the arrangement direction. That is, the inter-step region includes an overlapping region that overlaps the first electrode finger 31a and a non-overlapping region that does not overlap the first electrode finger 31a. A width W2 of the region between the first step 42a and the second step 42b is, for example, about 0.6 μm. A width W2a of the overlapping region in the inter-step region is, for example, about 0.3 μm.

A width W2b of the non-overlapping region in the inter-step region is, for example, about 0.3 μm. In this example embodiment, the lower surface of the second protective film 42 in the inter-step region is flat. Specifically, the lower surface of the second protective film 42 in the inter-step region is substantially flat across the region where the first electrode finger 31a is provided and the region where the first electrode finger 31a is not provided. The lower surface of the second protective film 42 refers to the surface of the second protective film 42 that faces the support substrate 11 (see FIG. 2).

The configuration of the second protective film 42 in plan view is substantially the same as that of the first protective film 41 illustrated in FIG. 1, and therefore repeated description thereof is omitted. Although not illustrated, the first step 42a is also provided on the opposite side in the arrangement direction of the plurality of electrode fingers 31 and 32 at a position overlapping portion of the second electrode finger 32a (see FIG. 1).

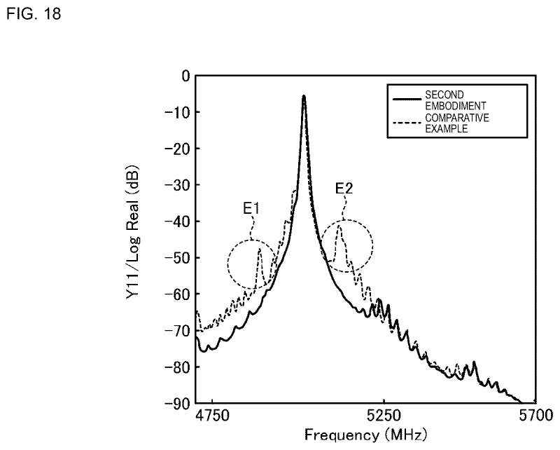

FIG. 18 is an explanatory diagram illustrating an example of the admittance characteristics of an acoustic wave device according to the Second Example Embodiment. As illustrated in FIG. 18, even though the first step 42a is provided on the second main surface 20b side of the piezoelectric layer 20, an acoustic wave device 10B according to the Second Example Embodiment exhibits reduced ripples indicated by dotted lines E1 and E2 compared to the comparative example, similarly to acoustic wave device 10 according to the First Example Embodiment. Furthermore, in the Second Example Embodiment, the peak width associated with the resonant frequency is narrower, which indicates that propagation loss is reduced. Furthermore, in the Second Example Embodiment, unlike in the First Example Embodiment, the first step is not provided on first protective film 41, and therefore the resonant frequency can be easily adjusted by changing the film thickness of first protective film 41.

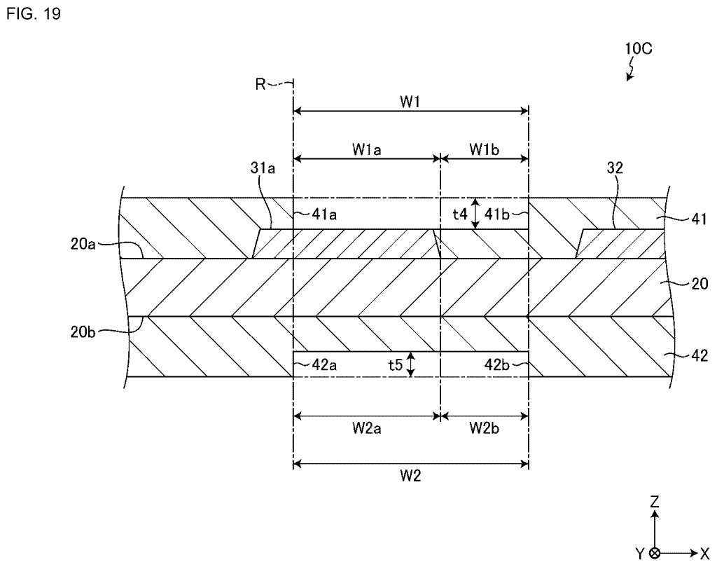

FIG. 19 is a sectional view of an acoustic wave device according to a Third Example Embodiment. As illustrated in FIG. 19, in an acoustic wave device 10C according to the Third Example Embodiment, a first step and a second step are provided on the first protective film 41 and also on the lower surface (the surface facing the support substrate 11 (see FIG. 2)) of the second protective film 42. In the following description, the region between the first steps 41a and 42a and the region between the second steps 41b and 42b are referred to as inter-step regions. The configuration of the IDT electrode 30, etc., is substantially the same as in the First Example Embodiment. In this example embodiment, the upper surfaces of first electrode finger 31a and first protective film 41 in the inter-step region are flat. Specifically, the upper surfaces of the first electrode finger 31a and the first protective film 41 in the inter-step region are formed to be substantially flat across the region where the first electrode finger 31a is provided and the region where the first electrode finger 31a is not provided. In this example embodiment, the lower surface of the second protective film 42 in the inter-step region is flat. Specifically, the lower surface of the second protective film 42 in the inter-step region is substantially flat across the region where the first electrode finger 31a is provided and the region where the first electrode finger 31a is not provided.

The inter-step regions are each provided to overlap portion of the first electrode finger 31a. A width W1 of the step region of the first protective film 41 and a width W2 of the step region of the second protective film are each about 0.8 μm, for example. A width W1a of the overlapping region of the step region of the first protective film 41 and a width W2a of the overlapping region of the step region of the second protective film are each about 0.5 μm, for example. A width W1b of the non-overlapping region of the step region of the first protective film 41 and a width W2b of the non-overlapping region of the step region of the second protective film are each about 0.3 μm, for example. A height t4 of the first step 41a and the second step 41b and a height t5 of the first step 42a and the second step 42b are about 40 nm, for example. In this example embodiment, the inter-step region of the first protective film 41 includes a region where the first protective film 41 is not provided. That is, the inter-step region of the first protective film 41 includes a region where the first electrode finger 31a is exposed.

Although an example is illustrated in which the first protective film 41 and the second protective film 42 have the same shape, the first protective film 41 and the second protective film 42 are not limited to this configuration. The first protective film 41 and the second protective film 42 may have different shapes.

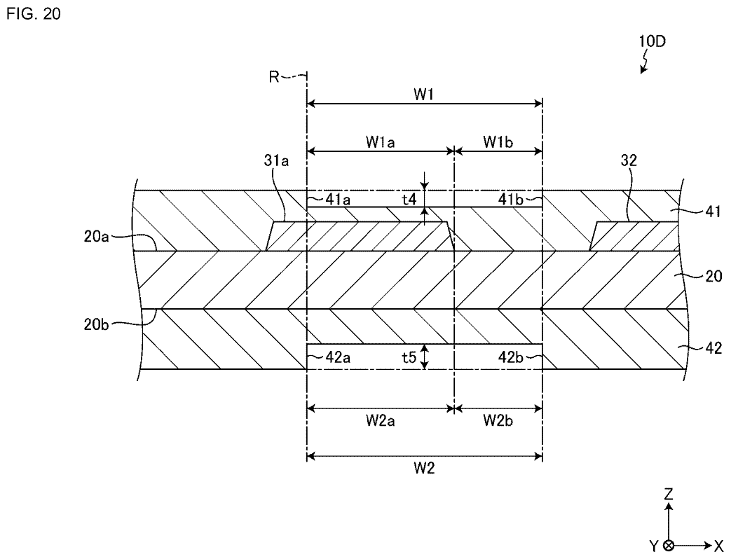

FIG. 20 is a sectional view of an acoustic wave device according to a Fourth Example Embodiment. As illustrated in FIG. 20, in an acoustic wave device 10D according to the Fourth Example Embodiment, the heights of first and second steps provided on the upper surface of the first protective film 41 are smaller than the heights of first and second steps provided on the lower surface of the second protective film 42 (the surface facing the support substrate 11 (see FIG. 2)). In the following description, the region between the first steps 41a and 42a and the region between the second steps 41b and 42b are referred to as inter-step regions. In this example embodiment, the upper surfaces of first electrode finger 31a and first protective film 41 in the inter-step region are flat. Specifically, the upper surface of first protective film 41 in the inter-step region is substantially flat across the region where the first electrode finger 31a is provided and the region where the first electrode finger 31a is not provided. The configuration of the IDT electrode 30, etc., is substantially the same as in the First Example Embodiment. In this example embodiment, the lower surface of the second protective film 42 in the inter-step region is flat. Specifically, the lower surface of the second protective film 42 in the inter-step region is substantially flat across the region where the first electrode finger 31a is provided and the region where the first electrode finger 31a is not provided.

The inter-step regions are each provided to overlap portion of the first electrode finger 31a. A width W1 of the step region of the first protective film 41 and a width W2 of the step region of the second protective film are each about 0.8 μm, for example. A width W1a of the overlapping region of the step region of the first protective film 41 and a width W2a of the overlapping region of the step region of the second protective film are each about 0.5 μm, for example. A width W1b of the non-overlapping region of the step region of the first protective film 41 and a width W2b of the non-overlapping region of the step region of the second protective film are each about 0.3 μm, for example. A height t4 of the first step 41a and the second step 41b is about 20 nm, and a height t5 of the first step 42a and the second step 42b is about 40 nm, for example. In this example embodiment, there is no region in the inter-step region of the first protective film 41 where the first electrode finger 31a is exposed.

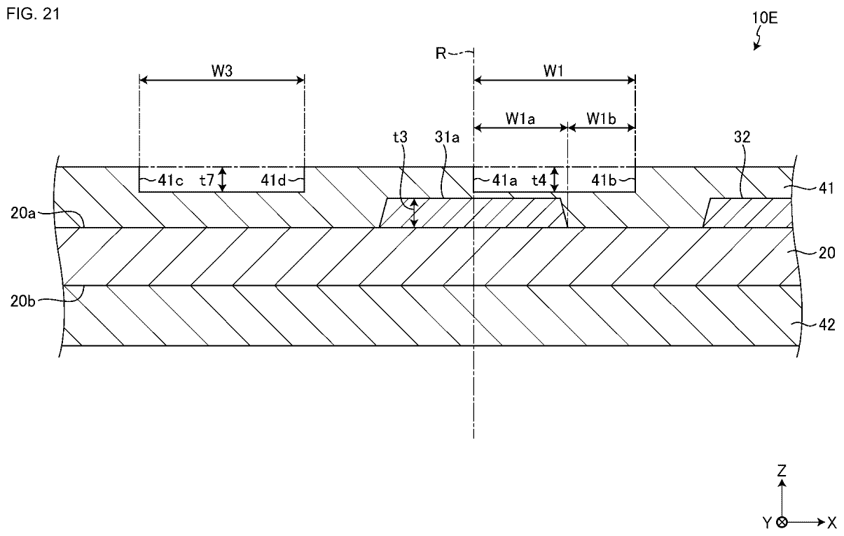

FIG. 21 is a sectional view of an acoustic wave device according to a Fifth Example Embodiment. As illustrated in FIG. 21, in an acoustic wave device 10E according to the Fifth Example Embodiment, a step is provided in the first protective film 41 outside the inter-step region between the first step 41a and the second step 41b. The configuration of the IDT electrode 30, etc., is substantially the same as in the First Example Embodiment. In this example embodiment, the upper surfaces of first electrode finger 31a and first protective film 41 in the inter-step region are flat. Specifically, the upper surface of first protective film 41 in the inter-step region is substantially flat across the region where the first electrode finger 31a is provided and the region where the first electrode finger 31a is not provided.

The inter-step region is provided so as to overlap portion of the first electrode finger 31a. A width W1 of the step region of the first protective film 41 is about 0.6 μm, for example. A width W1a of the overlapping region of the step region of the first protective film 41 is, for example, about 0.3 μm. A width W1b of the non-overlapping region of the step region of the first protective film 41 is, for example, about 0.3 μm. A height t4 of the first step 41a and the second step 41b is about 30 nm, for example.

As illustrated in FIG. 21, in this example embodiment, a third step 41c and a fourth step 41d are provided in the first protective film 41 in a region on the outside in the arrangement direction of the electrode fingers 31 and 32. In this example embodiment, the third step 41c is lower on the inner side in the arrangement direction of the electrode fingers 31 and 32. In this example embodiment, the fourth step 41d is lower on the outer side in the arrangement direction of the electrode fingers 31 and 32. The third step 41c is provided on the outside relative to the fourth step 41d in the arrangement direction of the electrode fingers 31 and 32. A width W3 of the region between the third step 41c and the fourth step 41d is, for example, about 0.6 μm. In this example embodiment, the upper surface of the first protective film 41 in the region between the third step 41c and the fourth step 41d is flat. In this example embodiment, a height t7 of the third step 41c and the fourth step 41d is about 30 nm, for example, which is the same as the height t4 of the first step 41a and the second step 41b. However, not limited to this configuration, the height t7 of the third step 41c and the fourth step 41d may be different from the height t4 of the first step 41a and the second step 41b.

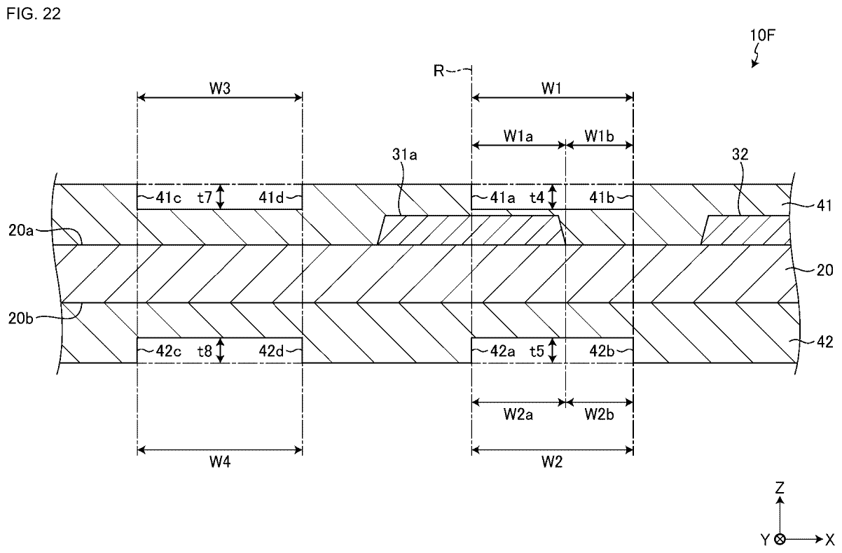

FIG. 22 is a sectional view of an acoustic wave device according to a Second Modification of the Fifth Example Embodiment. As illustrated in FIG. 22, in an acoustic wave device 10F according to the Second Modification, a first step and a second step are provided on the first protective film 41 and also on the lower surface of second protective film 42 (the surface facing support substrate 11 (see FIG. 2)). In this example embodiment, the upper surfaces of first electrode finger 31a and first protective film 41 in the inter-step region are flat. Specifically, the upper surface of first protective film 41 in the inter-step region is substantially flat across the region where the first electrode finger 31a is provided and the region where the first electrode finger 31a is not provided. The configuration of the IDT electrode 30, etc., is substantially the same as in the First Example Embodiment. In this example, the lower surface of the second protective film 42 in the inter-step region is flat. Specifically, the lower surface of the second protective film 42 in the inter-step region is substantially flat across the region where the first electrode finger 31a is provided and the region where the first electrode finger 31a is not provided.

The inter-step regions are each provided to overlap portion of the first electrode finger 31a. A width W1 of the step region of the first protective film 41 and a width W2 of the step region of the second protective film are each about 0.8 μm, for example. A width W1a of the overlapping region of the step region of the first protective film 41 and a width W2a of the overlapping region of the step region of the second protective film are each about 0.3 μm, for example. A width W1b of the non-overlapping region of the step region of the first protective film 41 and a width W2b of the non-overlapping region of the step region of the second protective film are each about 0.3 μm, for example. A height t4 of the first step 41a and the second step 41b is about 20 nm, and a height t5 of the first step 42a and the second step 42b is about 30 nm, for example. In this example embodiment, there is no region in the inter-step region of the first protective film 41 where the first electrode finger 31a is exposed.

As illustrated in FIG. 22, in this example embodiment, third steps 41c and 42c and fourth steps 41d and 42d are provided in the first protective film 41 and the second protective film 42 in a region on the outside in the arrangement direction of the electrode fingers 31 and 32. In this example embodiment, the third steps 41c and 42c are steps that are lower on the inner side in the arrangement direction of the electrode fingers 31 and 32. In this example embodiment, the fourth steps 41d and 42d are steps that are lower on the outer side in the arrangement direction of the electrode fingers 31 and 32. The third steps 41c and 42c are provided on the outside relative to the fourth steps 41d and 42d in the arrangement direction of the electrode fingers 31 and 32. A width W3 of the region between the third step 41c and the fourth step 41d and a width W4 of the region between the third step 42c and the fourth step 42d are, for example, about 0.6 μm. In this example embodiment, the upper surface of the first protective film 41 in the region between the third step 41c and the fourth step 41d and the lower surface of the second protective film 42 in the region between the third step 42c and the fourth step 42d are flat. In this example embodiment, heights t7 and t8 of the third steps 41c and 42c and the fourth steps 41d and 42d are about 30 nm, for example, the same as the heights of the first steps 41a and 42a and the second steps 41b and 42b. However, not limited to this configuration, the heights t7 and t8 of the third steps 41c and 42c and the fourth steps 41d and 42d may be different from the heights t4 and t5 of the first steps 41a and 42a and the second steps 41b and 42b.

Although an example is illustrated in which the first protective film 41 and the second protective film 42 have the same shape, the first protective film 41 and the second protective film 42 are not limited to this configuration. The first protective film 41 and the second protective film 42 may have different shapes.

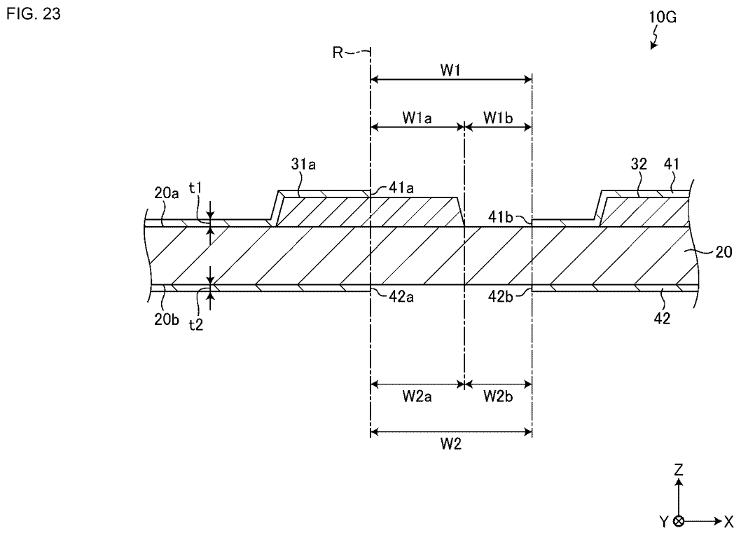

FIG. 23 is a sectional view of an acoustic wave device according to a Sixth Example Embodiment. As illustrated in FIG. 23, in an acoustic wave device 10G according to the Sixth Example Embodiment, the film thickness of the first protective film 41 and the film thickness of the second protective film 42 are smaller than the film thickness of the piezoelectric layer 20. Specifically, the film thickness of the piezoelectric layer 20 is, for example, about 360 nm. The film thickness of the first protective film 41 is about 30 nm, for example. The film thickness of the second protective film 42 is about 30 nm, for example. The configuration of the IDT electrode 30, etc., is substantially the same as in the First Example Embodiment.

A width W1 of the inter-step region of the first protective film 41 is, for example, about 0.5 μm. A width W1a of the overlapping region of the inter-step region of the first protective film 41 is, for example, about 0.3 μm. A width W1b of the non-overlapping region of the inter-step region of the first protective film 41 is, for example, about 0.2 μm. A width W2 of the inter-step region of the second protective film 42 is, for example, about 0.5 μm. A width W2a of the overlapping region of the inter-step region of the second protective film 42 is, for example, about 0.3 μm. A width W2b of the non-overlapping region in the inter-step region of the second protective film 42 is, for example, about 0.2 μm.

In the Sixth Example Embodiment, the first protective film 41, excluding the inter-step region, is provided to conform to the upper surfaces and side surfaces of the electrode fingers 31 and 32 and the first main surface 20a of the piezoelectric layer 20. The upper surface of the first protective film 41, excluding the inter-step region, is provided with projections and depressions that reflect the shapes of the electrode fingers 31 and 32. The second protective film 42, excluding the inter-step region, is flat along the second main surface 20b of the piezoelectric layer 20.

The inter-step region of the first protective film 41 is provided on the first protective film 41 farther inward in the arrangement direction than the first electrode finger 31a. The inter-step region of the second protective film 42 is flat along the second main surface 20b of the piezoelectric layer 20. In this example embodiment, the first protective film 41 and the second protective film 42 are not provided in the inter-step regions of the first protective film 41 and the second protective film 42. That is, the first electrode finger 31a and the first main surface 20a are exposed in the inter-step region of the first protective film 41. The second main surface 20b is exposed in the inter-step region of the second protective film 42.

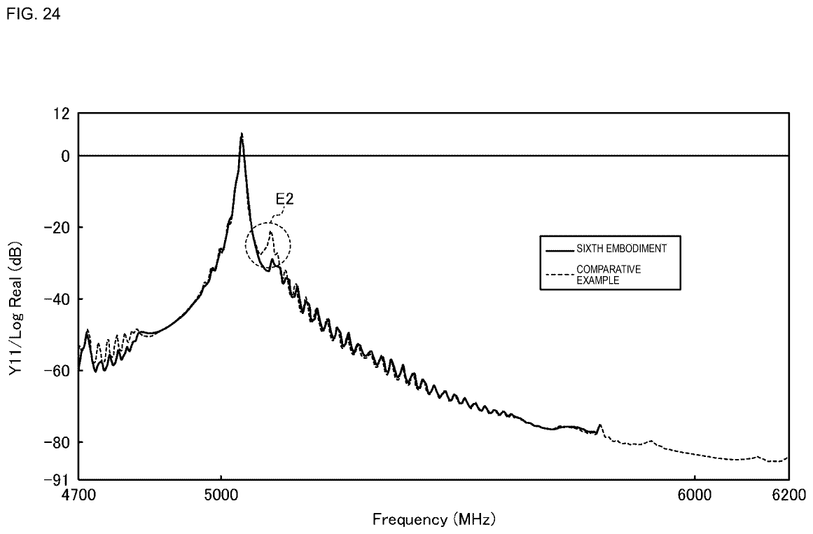

FIG. 24 is an explanatory diagram illustrating an example of the admittance characteristics of the acoustic wave device according to the Sixth Example Embodiment. As illustrated in FIG. 24, acoustic wave device 10G according to the Sixth Example Embodiment has a configuration in which the first step 42a is provided on the second main surface 20b side of piezoelectric layer 20. However, similarly to acoustic wave device 10 according to the First Example Embodiment, the ripple indicated by dotted line E2 is reduced or prevented compared to the comparative example. Furthermore, in the Sixth Example Embodiment, the peak width associated with the resonant frequency is narrower, which indicates that propagation loss is reduced or prevented.

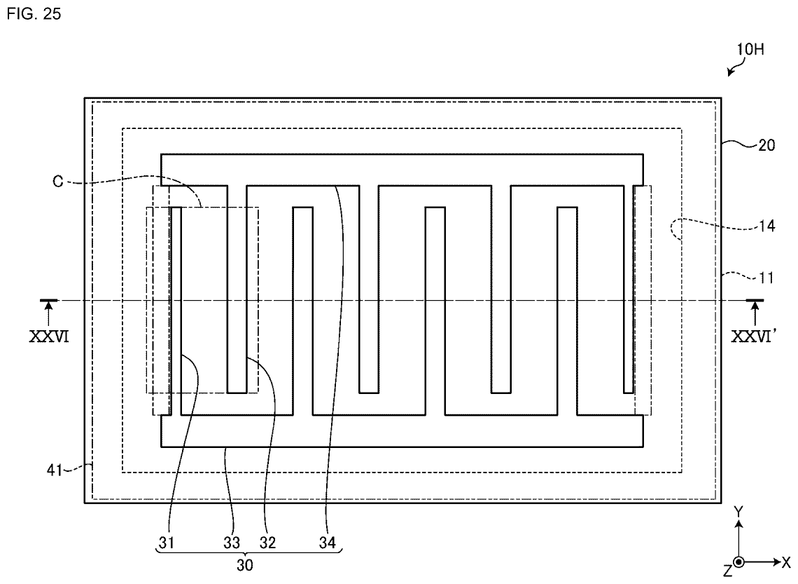

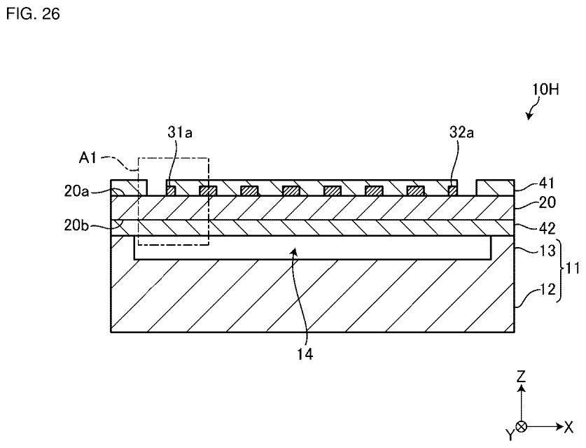

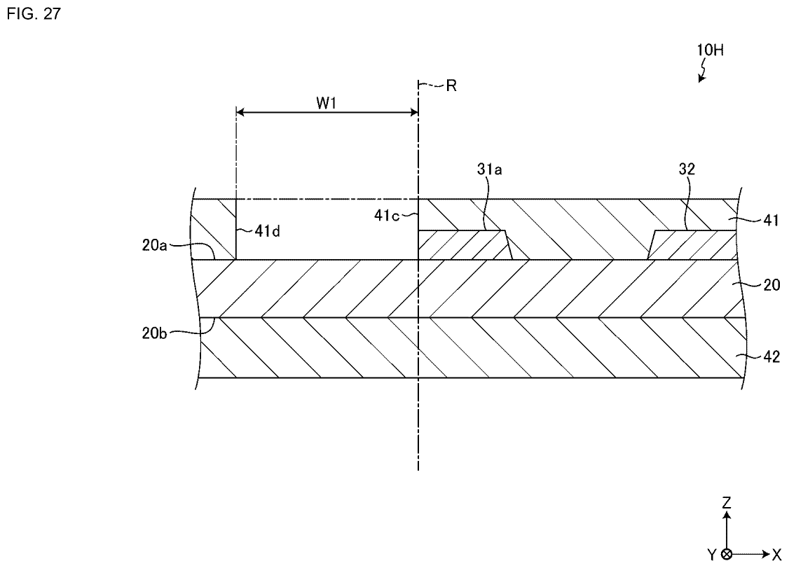

FIG. 25 is a plan view illustrating an acoustic wave device according to a Seventh Example Embodiment. FIG. 26 is a sectional view taken along line XXVI-XXVI′ in FIG. 25. FIG. 27 is an enlarged sectional view of region A1 illustrated in FIG. 26. As illustrated in FIGS. 25 to 27, in an acoustic wave device 10H according to the Seventh Example Embodiment, a first step 41c is provided at the outer end of first electrode finger 31a in the arrangement direction of the electrode fingers 31 and 32, and the first step 41c is lower on the outer side in the arrangement direction of the electrode fingers 31 and 32. Specifically, from the inner side in the arrangement direction of the electrode fingers 31 and 32, the first step 41c is defined by a portion where the first electrode finger 31a and the first protective film 41 are provided and a portion where the first main surface 20a is exposed. In this example embodiment, as illustrated in FIGS. 25 to 27, the first electrode finger 31a and the second electrode finger 32a have a smaller electrode width than the other electrode fingers among the electrode fingers 31 and 32. The electrode width of the first electrode finger 31a and the second electrode finger 32a is, for example, about 0.3 μm.

As illustrated in FIG. 27, in a region on the outside in the arrangement direction of the electrode fingers 31 and 32, the first protective film 41 includes a surface of a second step 41d where the side surface of the first protective film 41 is exposed along the Y direction. In this example embodiment, the second step 41d is lower on the inner side in the arrangement direction of the electrode fingers 31 and 32. In this example embodiment, in the region on the outer side in the arrangement direction of the electrode fingers 31a and 32, the second step 41d is defined by a portion where the first protective film 41 is not provided and a portion where the first protective film 41 is provided from the inner side in the arrangement direction of the electrode fingers 31 and 32.

The inter-step region is located at the outer end of the first electrode finger 31a in the arrangement direction of the electrode fingers 31 and 32. The side surface of the first protective film 41 at the first step 41c is disposed to overlap the outer end in the arrangement direction of the electrode fingers 31 and 32, and the side surface of the first protective film at the second step 41d is located further outward than the first step 41c in the arrangement direction. In other words, the inter-step region does not overlap the first electrode finger 31a. A width W1 of the inter-step region is, for example, about 0.6 μm. In this example embodiment, the first electrode finger 31a and the first protective film 41 are not provided in the inter-step region, and the first main surface 20a is exposed.

Thus, the first step 41c is provided to overlap the first electrode finger 31a, and therefore, in the region overlapping the first electrode finger 31a positioned outermost in the arrangement direction of the plurality of electrode fingers 31 and 32, the first protective film 41 is not provided in the region outward from the first step 41c in the arrangement direction and this region has a different acoustic impedance from the region where the first protective film 41 is stacked. As a result, an acoustic reflection surface R is provided at the first step (the portion overlapping the side surface of the first protective film 41).

As a result, the acoustic waves excited in the piezoelectric layer 20 are reflected by the acoustic reflection surface R, and therefore the acoustic wave device 10 can reduce or prevent leakage of acoustic waves in the arrangement direction of the multiple electrode fingers 31 and 32.

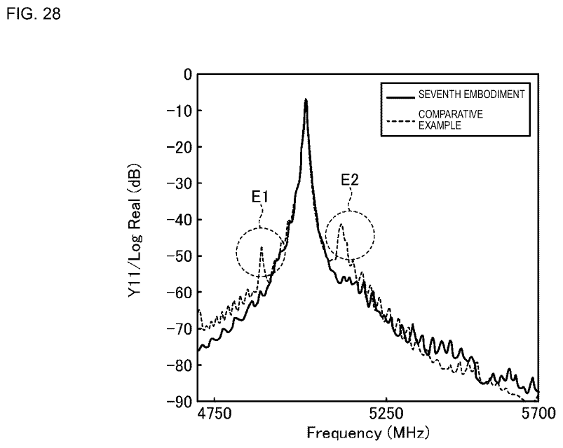

FIG. 28 is an explanatory diagram illustrating an example of the admittance characteristics of the acoustic wave device according to the Seventh Example Embodiment. As illustrated in FIG. 28, in the acoustic wave device according to a comparative example, ripples occur in a frequency range different from the resonant frequency. In the comparative example, particularly large ripples are generated, as indicated by the dotted lines E1 and E2. In contrast, in the acoustic wave device 10H according to the Seventh Example Embodiment, as a result of providing the first step 41c and second step 41d, the ripples indicated by dotted lines E1 and E2 are reduced or prevented compared to the comparative example. It is clear that since the peak width associated with the resonant frequency is smaller in the acoustic wave device 10H according to the Seventh Example Embodiment than in the acoustic wave device according to the comparative example, propagation loss and leakage of acoustic waves are reduced or prevented.

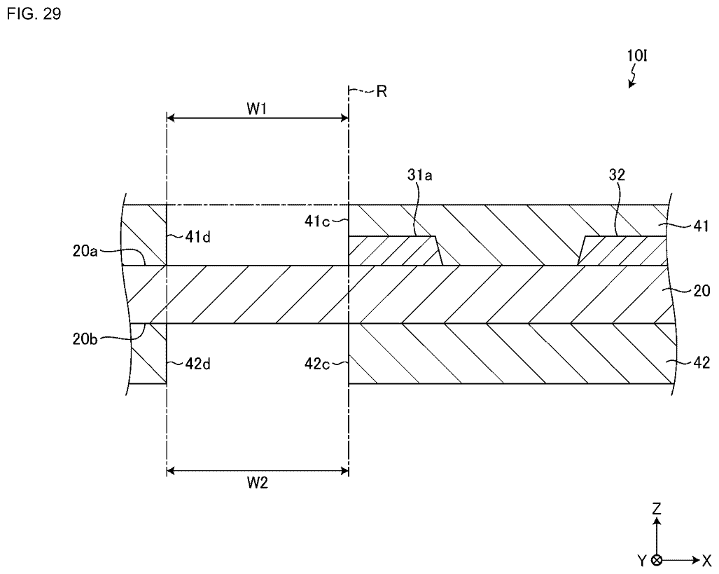

FIG. 29 is a plan view of an acoustic wave device according to a Third Modification of the Seventh Example Embodiment. As illustrated in FIG. 29, in an acoustic wave device 10I according to the Third Modification of the Seventh Example Embodiment, first steps 41c and 42c are provided at the outer end of the first electrode finger 31a in the arrangement direction of the electrode fingers 31 and 32, and the first steps 41c and 42c are steps that are lower on the outer side in the arrangement direction of the electrode fingers 31 and 32. Specifically, from the inner side in the arrangement direction of electrode fingers 31 and 32, the first step 41c is defined by a portion where the first electrode finger 31a and the first protective film 41 are provided and a portion where first main surface 20a is exposed, and the first step 42c is defined by a portion where the second protective film 42 is provided and a portion where the second main surface 20b is exposed. The configuration of the IDT electrode is the same as that in FIG. 27 described above.

As illustrated in FIG. 29, in a region on the outside in the arrangement direction of the electrode fingers 31 and 32, a second step 41d is provided in the first protective film 41 and a second step 42d is provided in the second protective film 42. In this example embodiment, the second steps 41d and 42d are steps that are lower on the inner side in the arrangement direction of the electrode fingers 31 and 32. In this example embodiment, in the region between the first electrode finger 31a and the adjacent electrode finger 32, from the inner side in the arrangement direction of the plurality of electrode fingers 31 and 32, the second step 41d is defined by a portion where the first protective film 41 is not provided and a portion where the first protective film 41 is provided, and the second step 42d is defined by a portion where the second protective film 42 is not provided and a portion where the second protective film 42 is provided.

The inter-step region is located at the outer end of the first electrode finger 31a in the arrangement direction of the electrode fingers 31 and 32. The side surface of the first protective film 41 at the first step 41c and the side surface of the second protective film 42 at the first step 42c are disposed to overlap the outer end in the arrangement direction of the electrode fingers 31 and 32, and the side surface of the first protective film 41 at the second step 41d and the side surface of the second protective film 42 at the second step 42d are located further outward than the first steps 41c and 42c in the arrangement direction. In other words, the inter-step regions do not overlap the first electrode finger 31a. Widths W1 and W2 of the inter-step regions are, for example, about 0.6 μm. In this example embodiment, the first electrode finger 31a and the first protective film 41 are not provided in the inter-step region, and the first main surface 20a is exposed. The second protective film 42 is not provided in the inter-step region, and the second main surface 20b is exposed.

Although an example is illustrated in which the first protective film 41 and the second protective film 42 have the same shape, the first protective film 41 and the second protective film 42 are not limited to this configuration. The first protective film 41 and the second protective film 42 may have different shapes.

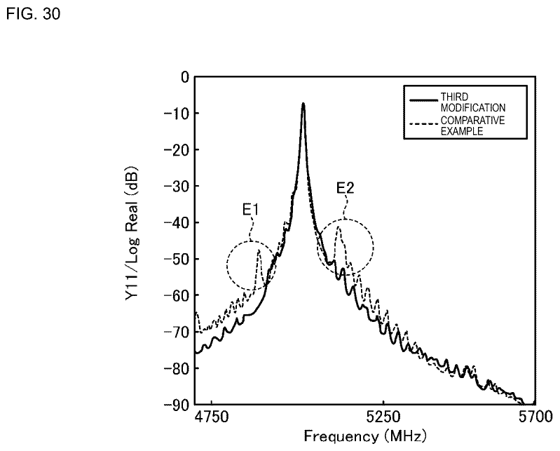

FIG. 30 is an explanatory diagram illustrating an example of the admittance characteristics of the acoustic wave device according to the Third Modification. As illustrated in FIG. 30, in an acoustic wave device according to a comparative example, ripples occur in a frequency range different from the resonant frequency. In the comparative example, particularly large ripples are generated, as indicated by the dotted lines E1 and E2. In contrast, in the acoustic wave device 10I according to the Third Modification, providing the first steps 41c and 42c and the second steps 41d and 42d reduces or prevents the ripples indicated by dotted lines E1 and E2 compared to the comparative example. It can be seen that the peak width associated with the resonant frequency is narrower in the acoustic wave device 10 according to the Third Modification than in the acoustic wave device according to the comparative example, which indicates that propagation loss and leakage of acoustic waves are reduced or prevented.

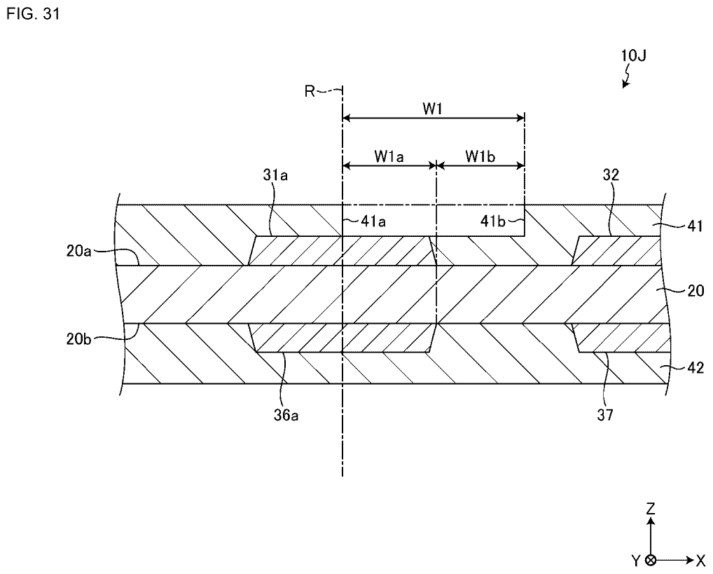

FIG. 31 is a sectional view of an acoustic wave device according to an Eighth Example Embodiment. In the acoustic wave device 10 according to the First Example Embodiment described above, a configuration is described in which the IDT electrode 30 is provided on the first main surface 20a of the piezoelectric layer 20. However, the present invention is not limited to this configuration. As illustrated in FIG. 31, an acoustic wave device 10J according to the Eighth Example Embodiment includes a first IDT electrode provided on the first main surface 20a of the piezoelectric layer 20 and a second IDT electrode provided on the second main surface 20b of the piezoelectric layer 20. The first IDT electrode and the second IDT electrode have substantially the same configuration as the IDT electrode 30 (see FIGS. 1 and 2).

Electrode fingers 36 and 37 of the second IDT electrode are provided in a region overlapping the electrode fingers 31 and 32 of the first IDT electrode. The electrode fingers 36 and 37 of the second IDT electrode are provided to have the same width and the same inter-electrode pitch as the electrode fingers 31 and 32 of the first IDT electrode. An inter-step region is in a region overlapping a first electrode finger 31a of the first IDT electrode and a first electrode finger 36a of the second IDT electrode.

In the Eighth Example Embodiment, the first IDT electrode and the second IDT electrode are provided on the first main surface 20a and the second main surface 20b of the piezoelectric layer 20, respectively, so that the temperature coefficient of frequency (TCF) can be improved.

FIG. 31 illustrates an example in which the first step 41a and the second step 41b illustrated in the First Example Embodiment are provided, but the present invention is not limited to this configuration. The Eighth Example Embodiment can be combined with each of the above-described example embodiments and modifications.

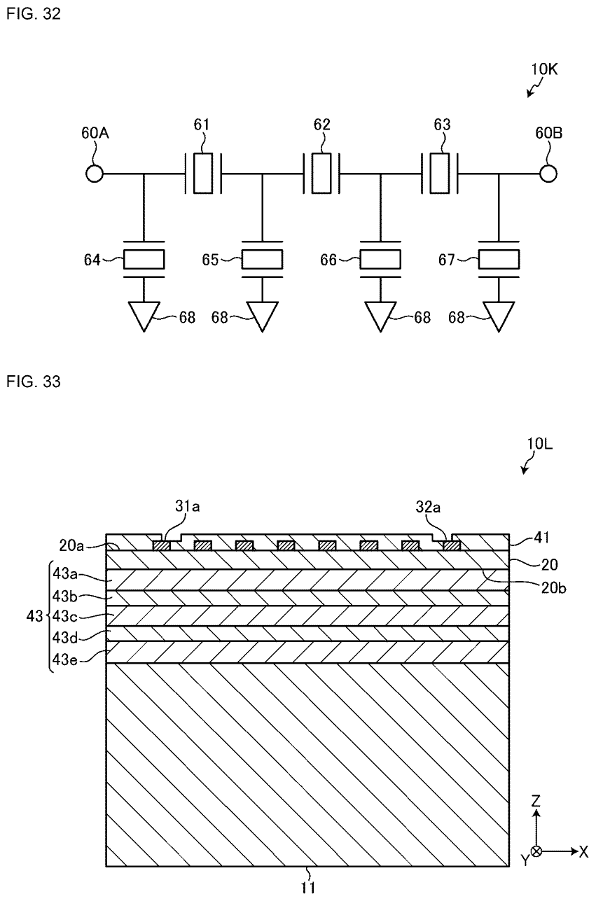

FIG. 32 is a circuit diagram illustrating an acoustic wave filter device according to a Ninth Example Embodiment.

As illustrated in FIG. 32, an acoustic wave filter device 10K according to the Ninth Example Embodiment includes a plurality of series arm resonators 61, 62, and 63 and a plurality of parallel arm resonators 64, 65, 66, and 67. The plurality of series arm resonators 61, 62, and 63 are connected in series on a signal path between an input terminal 60A and an output terminal 60B. The plurality of parallel arm resonators 64, 65, 66, and 67 are connected in parallel with each other between the signal path between the input terminal 60A and the output terminal 60B and ground 68. The acoustic wave filter device 10K according to the Ninth Example Embodiment is a so-called ladder filter.

One terminal of each of the series-connected series arm resonators 61, 62, and 63 is electrically connected to the input terminal 60A, and the other terminal is electrically connected to the output terminal 60B. One terminal of the parallel arm resonator 64 is electrically connected to the input terminal 60A, and the other terminal is electrically connected to the ground 68. One terminal of the parallel arm resonator 65 is electrically connected to a signal path connecting the series arm resonators 61 and 62 to each other, and the other terminal is electrically connected to the ground 68. One terminal of the parallel arm resonator 66 is electrically connected to a signal path connecting the series arm resonators 62 and 63 to each other, and the other terminal is electrically connected to the ground 68. One terminal of the parallel arm resonator 67 is electrically connected to the output terminal 60B, and the other terminal is electrically connected to the ground 68.

In this example embodiment, the plurality of series arm resonators 61, 62, and 63 and the plurality of parallel arm resonators 64, 65, 66, and 67 use protective films with different configurations. This makes it possible to obtain a better output waveform as a filter.

Although an example in which the first and second steps illustrated in the first and Second Modifications are used in combination with each other is illustrated in the acoustic wave filter device 10K according to the Ninth Example Embodiment, the present invention is not limited to this configuration. The Ninth Example Embodiment can be combined with any of the above-described example embodiments and modifications.

FIG. 33 is a sectional view of an acoustic wave device according to a Tenth Example Embodiment. In the acoustic wave device 10 according to the First Example Embodiment described above, a so-called membrane structure is described in which the support substrate 11 includes the cavity 14 and the cavity 14 (hollow portion) is provided on the second main surface 20b side of the piezoelectric layer 20. However, the present invention is not limited to this configuration.

As illustrated in FIG. 33, in an acoustic wave device 10L according to the Tenth Example Embodiment, an acoustic multilayer film 43 is stacked on the second main surface 20b of the piezoelectric layer 20. The acoustic multilayer film 43 has a multilayer structure including low acoustic impedance layers 43a, 43c, and 43e, which have a relatively low acoustic impedance, and high acoustic impedance layers 43b and 43d, which have a relatively high acoustic impedance. The low acoustic impedance layers 43a, 43c, and 43e are, for example, SiO₂ layers, and the high acoustic impedance layers 43b and 43d are, for example, metal layers such as W or Pt or dielectric layers such as AlN or SiN. When the acoustic multilayer film 43 is used, bulk waves in the first-order thickness-shear mode can be confined within the piezoelectric layer 20 without using the cavity 14.

In acoustic wave device 10L, by setting d/p to about 0.5 or less, for example, resonance characteristics based on bulk waves in the first-order thickness-shear mode can be obtained. Note that the number of stacked layers of the low acoustic impedance layers 43a, 43c, and 43e and the high acoustic impedance layers 43b and 43d in the acoustic multilayer film 43 is not particularly limited. It is sufficient that at least one high acoustic impedance layer 43b or 43d be disposed farther from piezoelectric layer 20 than the low acoustic impedance layers 43a, 43c, and 43e.

The low acoustic impedance layers 43a, 43c, and 43e and the high acoustic impedance layers 43b and 43d may include any suitable material so long as the above acoustic impedance relationship is satisfied. For example, the low acoustic impedance layers 43a, 43c, and 43e may include silicon oxide or silicon oxynitride. The high acoustic impedance layers 43b and 43d may include alumina, silicon nitride, a metal, and so on.

FIG. 33 illustrates an example in which the first step 41a and the second step 41b illustrated in the First Example Embodiment are provided, but the present invention is not limited to this configuration. The Tenth Example Embodiment can be combined with each of the above-described example embodiments and modifications.

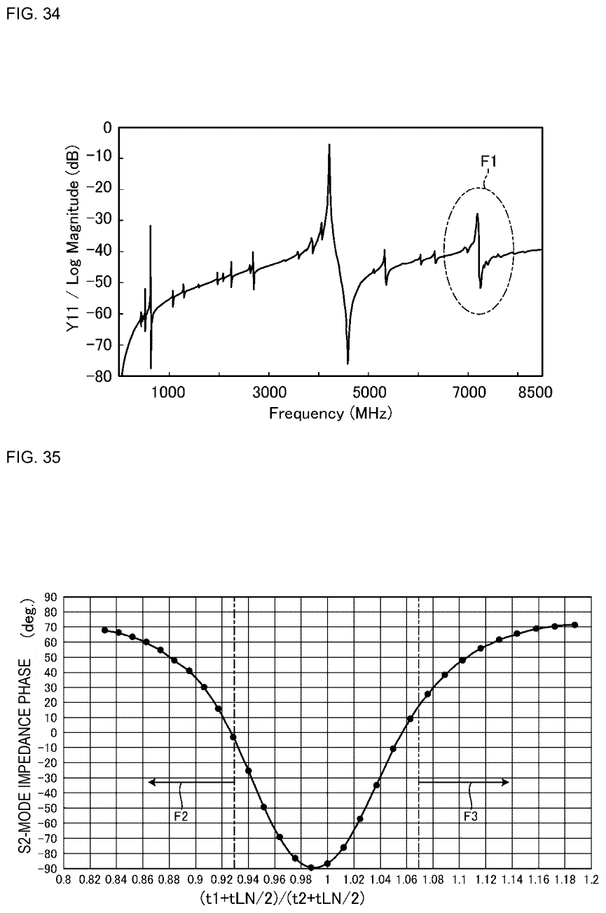

FIG. 34 is an explanatory diagram illustrating an example of the admittance characteristics of an acoustic wave device according to an Eleventh Example Embodiment. FIG. 35 is an explanatory diagram illustrating an example of the impedance phase in a higher-order mode. The acoustic wave device according to the Eleventh Example Embodiment illustrated in FIG. 34 is configured such that the first protective film 41 and the second protective film 42 have different film thicknesses in the acoustic wave device 10 according to the First Example Embodiment described above.

FIG. 34 illustrates frequency characteristics of the absolute value of admittance in the acoustic wave device according to the Eleventh Example Embodiment. As illustrated in FIG. 34, in the acoustic wave device according to the Eleventh Example Embodiment, higher-order mode resonance (hereinafter referred to as S2 mode) occurs in a frequency range indicated by a dashed dotted line F1 that is different from the resonant frequency.

The horizontal axis of the graph illustrated in FIG. 35 represents the ratio ((t1+tLN/2)/(t2+tLN/2)) of the sum (t1+tLN/2) of the film thickness t1 of the first protective film 41 and ½ of the film thickness tLN of the piezoelectric layer 20 to the sum (t2+tLN/2) of the film thickness t2 of the second protective film 42 and ½ of the film thickness tLN of the piezoelectric layer 20. The vertical axis of the graph illustrated in FIG. 35 corresponds to the intensity of the S2 mode.

In FIG. 35, the range indicated by arrows F2 and F3 indicates the ratio (t1+tLN/2)/(t2+tLN/2) in the configuration of the acoustic resonator device described in Japanese Unexamined Patent Application Publication No. 2022-524136. In the acoustic resonator device described in Japanese Unexamined Patent Application Publication No. 2022-524136, the ratio (t1+tLN/2)/(t2+tLN/2) is 0.93 or less and 1.07 or more, and the intensity of the S2 mode is high.

In contrast, in the Eleventh Example Embodiment, the ratio (t1+tLN/2)/(t2+tLN/2) is in the range of about 0.94 or more and about 1.06 or less, for example, and the intensity of the S2 mode is smaller than that of the acoustic resonator device described in Japanese Unexamined Patent Application Publication No. 2022-524136. In other words, in the Eleventh Example Embodiment, when A is the total distance from the center of the film thickness of the piezoelectric layer 20 to the top surface of the first protective film 41 and B is the total distance from the center of the film thickness of the piezoelectric layer 20 to the top surface of the second protective film 42, it is preferable that the value of A/B be about 1−0.06 or more and about 1+0.06 or less.

Although a case in which the first protective film 41 and the second protective film 42 have different film thicknesses in the acoustic wave device 10 according to the First Example Embodiment has been described in the Eleventh Example Embodiment, the present invention is not limited to this configuration. The relationship between the film thickness t1 of the first protective film 41, the film thickness tLN of the piezoelectric layer 20, and the film thickness t2 of the second protective film 42 in the Eleventh Example Embodiment can be combined with any of the example embodiments and modifications described above.

The shapes, widths, film thicknesses, etc. of the first protective film 41, the second protective film 42, and the IDT electrode 30 in the above-described example embodiments and modifications are merely examples and can be changed as appropriate. For example, the side surfaces of the first protective film 41 and the second protective film 42 may be formed in a tapered shape. The first step and the second step may have the same height, and the inter-step regions may have the same width. Alternatively, the first steps overlapping the first electrode finger 31a and the second electrode finger 32a may have different widths and film thicknesses due to variations in the manufacturing process, for example, and may have a different height from the second steps. Furthermore, the first step and the second step may be formed to have tapered shapes.

The first step 41a and the second step 42b illustrated in the above-described example embodiments and modifications are merely examples and can be modified as appropriate. At least one of the first step 41a and the second step 42b may be provided in a region overlapping two electrode fingers (the first electrode finger 31a and the electrode finger 32) or three electrode fingers (the first electrode finger 31a, the electrode finger 32, and the electrode finger 31) positioned on the outer side in the arrangement direction.

The above-described example embodiments are intended to facilitate understanding of the present invention and are not intended to limit the present invention. Example embodiments of the present invention may be modified or improved without departing from the spirit and scope of the present invention, and equivalents thereof are also included in the present invention.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer including a first main surface and a second main surface facing the first main surface in a first direction;
an IDT electrode provided on at least one of the first main surface or the second main surface of the piezoelectric layer and including a plurality of electrode fingers arranged in an arrangement direction;
a support facing the second main surface of the piezoelectric layer and including an acoustic reflection portion on a side adjacent the second main surface of the piezoelectric layer; and
a protective film provided on at least one of the first main surface or the second main surface of the piezoelectric layer; wherein
in a region that overlaps, in plan view in the first direction, a first electrode finger, among the plurality of electrode fingers, that is located outermost in the arrangement direction, the protective film includes a surface of a first step where a side surface of the protective film is exposed in a direction intersecting a direction in which the first electrode finger extends; and
d/p is about 0.5 or less, where d is a thickness of the piezoelectric layer and p is a center-to-center distance between adjacent electrode fingers.

2. The acoustic wave device according to claim 1, wherein
in a region between the first electrode finger and an electrode finger adjacent to the first electrode finger, the protective film includes a surface of a second step where a side surface of the protective film is exposed in a direction intersecting the direction in which the first electrode finger extends;
the first step is lower on an inner side in the arrangement direction; and
the second step is lower on an outer side in the arrangement direction.

3. The acoustic wave device according to claim 2, wherein
the protective film includes a first protective film provided on the first main surface of the piezoelectric layer and covering the IDT electrode;
in a region that overlaps a first electrode finger, among the plurality of electrode fingers, that is located outermost in the arrangement direction, the first protective film includes a surface of a first step where a side surface of the protective film is exposed in a direction intersecting the direction in which the first electrode finger extends; and
in a region between the first electrode finger and an electrode finger adjacent to the first electrode finger, the first protective film includes a surface of a second step where a side surface of the protective film is exposed in a direction intersecting the direction in which the first electrode finger extends.

4. The acoustic wave device according to claim 2, wherein
the protective film includes a first protective film provided on the first main surface of the piezoelectric layer and covering the IDT electrode, and a second protective film provided on the second main surface of the piezoelectric layer;
in a region that overlaps a first electrode finger, among the plurality of electrode fingers, that is located outermost in the arrangement direction, the second protective film includes a surface of a first step where a side surface of the protective film is exposed in a direction intersecting a direction in which the first electrode finger extends; and
in a region between the first electrode finger and an electrode finger adjacent to the first electrode finger, the second protective film includes a surface of a second step where a side surface of the protective film is exposed in a direction intersecting the direction in which the first electrode finger extends.

5. The acoustic wave device according to claim 2, wherein
the protective film includes a first protective film provided on the first main surface of the piezoelectric layer and covering the IDT electrode, and a second protective film provided on the second main surface of the piezoelectric layer;
in a region that overlaps a first electrode finger, among the plurality of electrode fingers, that is located outermost in an arrangement direction of the plurality of electrode fingers, the first protective film and the second protective film each include a surface of a first step where a side surface of the protective film is exposed in a direction intersecting the direction in which the first electrode finger extends; and
in a region between the first electrode finger and an electrode finger adjacent to the first electrode finger, the first protective film and the second protective film each include a surface of a second step where a side surface of the protective film is exposed in a direction intersecting the direction in which the first electrode finger extends.

6. The acoustic wave device according to claim 5, wherein heights of the first step and the second step defined by the first protective film are smaller than heights of the first step and the second step defined by the second protective film.

7. The acoustic wave device according to claim 1, wherein a third step is provided in a region outside the first electrode finger in the arrangement direction and does not overlap the IDT electrode.

8. The acoustic wave device according to claim 1, wherein the protective film has a smaller film thickness than the piezoelectric layer.

9. The acoustic wave device according to claim 1, wherein
in a region that is outside the first electrode finger in the arrangement direction and does not overlap the IDT electrode, the protective film includes a surface of a second step where a side surface of the protective film is exposed in a direction intersecting the direction in which the first electrode finger extends;
the first step is lower on an outer side in the arrangement direction; and
the second step is lower on an inner side in the arrangement direction.

10. The acoustic wave device according to claim 9, wherein
the protective film includes a first protective film provided on the first main surface of the piezoelectric layer and covering the IDT electrode;
at an outer end portion, in the arrangement direction, of a first electrode finger, among the plurality of electrode fingers, that is located outermost in the arrangement direction, the first protective film includes a surface of a first step where a side surface of the protective film is exposed in a direction intersecting the direction in which the first electrode finger extends; and
in a region that is outside the first electrode finger in the arrangement direction and does not overlap the IDT electrode, the first protective film includes a surface of a second step where a side surface of the protective film is exposed in a direction intersecting the direction in which the first electrode finger extends.

11. The acoustic wave device according to claim 9, wherein
the protective film includes a first protective film provided on the first main surface of the piezoelectric layer and covering the IDT electrode and a second protective film provided on the second main surface of the piezoelectric layer;
at an outer end portion, in the arrangement direction, of a first electrode finger, among the plurality of electrode fingers, that is located outermost in the arrangement direction, the first protective film and the second protective film each include a surface of a first step where a side surface of the protective film is exposed in a direction intersecting the direction in which the first electrode finger extends; and
in a region that is outside the first electrode finger in the arrangement direction and does not overlap the IDT electrode, the first protective film and the second protective film each include a surface of a second step where a side surface of the protective film is exposed in a direction intersecting the direction in which the first electrode finger extends.

12. The acoustic wave device according to claim 1, wherein the IDT electrode is provided on both the first main surface and the second main surface of the piezoelectric layer.

13. The acoustic wave device according to claim 1, wherein the protective film includes silicon oxide.

14. An acoustic wave filter device comprising:
at least one resonator including the acoustic wave device according to claim 1.

15. The acoustic wave filter device according to claim 14, further comprising:
an input terminal;
an output terminal;
a series arm connecting the input terminal and the output terminal to each other; and
a parallel arm connecting a node of the series arm and ground to each other; wherein
the at least one resonator includes a plurality of resonators including a series arm resonator provided in the series arm and a parallel arm resonator provided in the parallel arm;
the first step is defined by the protective film of each of the series arm resonator and the parallel arm resonator; and
a height of the first step defined by the protective film of the series arm resonator is different from a height of the first step defined by the protective film of the parallel arm resonator.

16. The acoustic wave filter device according to claim 14, further comprising:
an input terminal;
an output terminal;
a series arm connecting the input terminal and the output terminal to each other; and
a parallel arm connecting a node of the series arm and ground to each other; wherein
the at least one resonator includes a plurality of resonators including a series arm resonator provided in the series arm and a parallel arm resonator provided in the parallel arm; and
the protective film of the series arm resonator has a different configuration from the protective film of the parallel arm resonator.

17. The acoustic wave device according to claim 1, wherein the piezoelectric layer includes lithium niobate or lithium tantalate and is 120°±10° rotated Y-cut or 90°±10° rotated Y-cut.

18. The acoustic wave device according to claim 1, wherein the protective film includes a first protective film provided on the first main surface of the piezoelectric layer and covering the IDT electrode, and a second protective film provided on the second main surface of the piezoelectric layer.

19. The acoustic wave device according to claim 1, wherein the protective film has a greater film thickness than the IDT electrode.

20. The acoustic wave device according to claim 1, wherein
the protective film includes a first protective film provided on the first main surface of the piezoelectric layer and covering the IDT electrode, and a second protective film provided on the second main surface of the piezoelectric layer; and
when A is a total distance from a center of a film thickness of the piezoelectric layer to a top surface of the first protective film and B is a total distance from the center of the film thickness of the piezoelectric layer to a top surface of the second protective film, a value of A/B is about 1−0.06 or more and about 1+0.06 or less.

21. The acoustic wave device according to claim 1, wherein
the protective film includes a first protective film provided on the first main surface of the piezoelectric layer and covering the IDT electrode and a second protective film provided on the second main surface of the piezoelectric layer; and
an upper surface of the first protective film and a lower surface of the second protective film are flat.

22. The acoustic wave device according to claim 1, wherein d/p is about 0.24 or less.

23. The acoustic wave device according to claim 1, wherein
when viewed in a direction perpendicular to the electrode fingers, an excitation region is a region where adjacent electrode fingers, among the electrode fingers, overlap each other, and lies between centers of the adjacent electrode fingers in a direction perpendicular to the electrode fingers; and
when MR is a metallization ratio of the electrode fingers to the excitation region, MR satisfies MR≤about 1.75(d/p)+0.075.

24. The acoustic wave device according to claim 1, wherein the piezoelectric layer includes lithium tantalate or lithium niobate.

25. The acoustic wave device according to claim 24, wherein
Euler angles (φ, θ, ψ) of the lithium niobate or lithium tantalate of the piezoelectric layer lie within a range of Formula (1), Formula (2), or Formula (3) below:
(0°±10°, 0° to 20°, any ψ) Formula (1)
(0°±10°, 20° to 80°, 0° to 60°(1−(θ−50)²/900)^{1/2}) or (0°±10°, 20° to 80°, [180°−60°(1−(θ−50)²/900)^{1/2}] to 180°) Formula (2)
(0°±10°, [180°−30°(1−(ψ−90)²/8100)^{1/2}] to 180°, any ψ) Formula (3).

26. The acoustic wave device according to claim 1, wherein the acoustic reflection portion includes a hollow portion, and a portion of the support and a portion of the piezoelectric layer face each other across the hollow portion.

27. The acoustic wave device according to claim 1, wherein the acoustic reflection portion includes an acoustic reflection film including a high acoustic impedance layer having a relatively high acoustic impedance and a low acoustic impedance layer having a relatively low acoustic impedance, and at least a portion of the support and at least a portion of the piezoelectric layer face each other with the acoustic reflection film interposed therebetween.
